(19) United States
(12) Patent Application Publication
(10) Pub. No.: US 2026/0278771 A1
(43) Pub. Date: Sep. 17, 2026

(54) COMPUTER SYSTEM, SAMPLE OBSERVATION METHOD, AND PROGRAM

(71) Applicant: Hitachi High-Tech Corporation, Tokyo (JP)

(72) Inventors: Yuki DOI, Tokyo (JP); Atsushi MIYAMOTO, Tokyo (JP); Naoaki KONDO, Tokyo (JP); Kosuke MATSUMOTO, Tokyo (JP); Hirohiko KITSUKI, Tokyo (JP)

(21) Appl. No.: 19/120,318

(22) PCT Filed: Dec. 27, 2022
(86) PCT No.: PCT/JP2022/048388

§ 371 Date: Apr. 11, 2025

(51) Int. Cl. G06T 7/00; G01N 21/88; G01N 21/95; G06T 5/30; G06V 10/764

(52) U.S. Cl. CPC G06T 7/0008; G01N 21/8851; G01N 21/9501; G06T 5/30; G06V 10/764; G01N 2021/8854; G01N 2021/8887; G06T 2207/30148; G06T 2207/30168

(57) ABSTRACT

Provided is a technology that can realize preferable image quality quantification regarding a technology of a sample observation apparatus and the like. A computer system in a sample observation apparatus for observing a sample includes at least one processor and at least one memory, and the processor determines a plurality of evaluation partial areas Si in an image 201 captured of the sample, and calculates a plurality of image quality evaluation values Ei for evaluating a plurality of different image quality items by calculating an image quality evaluation value Ei for each evaluation partial area Si on the basis of the plurality of evaluation partial areas Si.

### TECHNICAL FIELD

The present disclosure relates to a sample observation technology, and, for example, relates to a sample observation apparatus and the like having a functionality to observe defects, anomalies, and the like (collectively referred to as defects in some cases), circuit patterns, and the like in a sample such as a semiconductor wafer.

### BACKGROUND ART

In the manufacture of semiconductor wafers, it is important to promptly start up the manufacturing process and quickly transition to a high-yield mass production system in order to ensure profits. For this purpose, various inspecting apparatuses, observation apparatuses, measurement apparatuses, and the like have been introduced in the manufacturing lines. For example, semiconductor wafers which are samples are inspected for defects at an inspecting apparatus. The inspecting apparatus outputs, as defect candidate coordinates, coordinate information representing the positions/sites of defects in a sample. The output defect candidate coordinates are supplied to a sample observation apparatus which is an observation apparatus that observes defects.

The sample observation apparatus captures images of defect candidates on the wafer surface at a high resolution on the basis of the defect candidate coordinates, and outputs the captured images. As the sample observation apparatuses, observation apparatuses using optical microscopes and observation apparatuses using scanning electron microscopes (SEMs) have widely been used. These apparatuses are, in other words, charged particle beam devices including a mechanism to irradiate a sample with a charged particle beam, and have a functionality to perform image capturing, measurement, observation, evaluation, inspection, and the like (collectively referred to as observation in some cases) of the sample.

Automation of observation work using observation apparatuses has been desired for a mass production line of semiconductor wafers. For automation in a mass production line, an observation apparatus has a functionality to perform defect image automatic collection, in other words, automatic defect review (ADR), in which images captured at defect positions in a sample are automatically collected, and a functionality to perform defect image automatic classification, in other words, automatic defect classification (ADC), in which the collected defect images are classified automatically, in some cases. By these functionalities, classified defect images can automatically be obtained.

Defect candidate coordinates output by an inspecting apparatus include errors. Since there are differences between the coordinate system of defect candidate coordinates in the inspecting apparatus and the coordinate system in an observation apparatus, due to misalignment caused by the differences, defect candidates cannot be found in some cases even if images are captured at defect candidate coordinates in the observation apparatus. Accordingly, in ADR, the observation apparatus performs image capturing in a widened visual field having its center at defect candidate coordinates, and detects a defect candidate site from an image obtained by this image capturing. The observation apparatus captures an image of the thus-obtained defect candidate site at a high magnification/high resolution, and outputs the captured image as an observation image.

In addition, observation images captured of a semiconductor wafer go through a process of image quality enhancement (i.e., image quality heightening) using an image quality enhancement engine for the purpose of visibility enhancement, in some cases.

Prior art examples include JP-2012-142299-A (Patent Document 1). Patent Document 1 describes a technology in which high-quality images with reduced noise components are acquired from images of a sample obtained by image capturing with a scanning charged particle microscope, and the precision of image processing is enhanced.

### PRIOR ART DOCUMENT

### Patent Document

Patent Document 1: JP-2012-142299-A

### SUMMARY OF THE INVENTION

### Problems to be Solved by the Invention

Patent Document 1 describes a technical example of a process of the image quality enhancement on images captured of a semiconductor wafer. In the description of Patent Document 1, a degradation function of images is calculated on the basis of image capturing conditions, sample information, and the like, and images with heightened quality are acquired by an image restoration process using the degradation function.

Conventionally, whether the quality of observation images obtained using image capturing functionalities or image quality enhancement engines is good or bad has been judged by visual evaluation by users. Accordingly, there are such problems as increase in work cost of users and ambiguity of judgment criteria of humans.

In view of this, if the quality of images captured of wafers can be quantified in a system of an observation apparatus or the like, these problems can be solved.

However, when it is attempted to quantify image quality, the image quality required for images, in other words, an image quality evaluation value, a parameter value, or the like, is not necessarily of one item, and includes two or more items in some cases. For example, the image quality considered to be required for preferable observation, inspection, and the like of images captured of a circuit pattern of a wafer includes a plurality of elements and parameter values such as sharpness, defect visibility, and a noise amount (i.e., a degree of noise suppression).

Conventional image quality quantification methods have not taken into consideration such a plurality of elements and parameter values of the quality of images captured with such a microscope as an SEM (i.e., a charged particle beam device or an image capturing device). It is considered that, in images captured of a wafer, preferable areas for calculating image quality evaluation values are different for such different image quality elements and parameter values in some cases.

An object of the present disclosure is to provide a technology that can realize preferable image quality quantification regarding the technology of sample observation apparatuses described above and the like.

### Means for Solving the Problems

A representative embodiment of the present disclosure has a configuration described below. A computer system according to an embodiment is a computer system in a sample observation apparatus for observing a sample, the computer system including at least one processor and at least one memory. The processor determines a plurality of evaluation partial areas in an image captured of the sample, and calculates a plurality of image quality evaluation values for evaluating a plurality of different image quality items by calculating an image quality evaluation value for each evaluation partial area on the basis of the plurality of evaluation partial areas.

### Advantages of the Invention

According to a representative embodiment of the present disclosure, preferable image quality quantification can be realized regarding the technology of sample observation apparatuses described above and the like. Problems, configurations, advantages, and the like other than those described above are described in Mode for Carrying Out the Invention.

### BRIEF DESCRIPTION OF THE DRAWINGS

FIG. 1 is a figure depicting a configuration of a system including a sample observation apparatus of a first embodiment.

FIG. 2 is a figure depicting a processing procedure and a functional block configuration of the sample observation apparatus and a method therefor of the first embodiment.

FIG. 3 is a figure depicting data examples of image quality evaluation value information and image quality evaluation results in the first embodiment.

FIG. 4 is a figure depicting examples of image quality evaluation values in the first embodiment.

FIG. 5 is a figure depicting examples of image quality evaluation values in the first embodiment.

FIG. 6 is a figure depicting Step S6 of setting in the first embodiment.

FIG. 7 is a figure depicting process examples of Steps S2 and S3 in the first embodiment.

FIG. 8 is a figure depicting examples of the correspondence between evaluation partial areas Si and image quality evaluation values Ei in the first embodiment.

FIG. 9 is a figure depicting a case where evaluation partial areas Si overlap and a case where evaluation partial areas Si do not overlap in the first embodiment.

FIG. 10 is a figure depicting a detailed process example of Step S2 in the first embodiment.

FIG. 11 is a figure depicting a process example of classification (Step S21) using design data in the first embodiment.

FIG. 12 is a figure depicting a process example of classification (Step S21) using image capturing conditions in the first embodiment.

FIG. 13 is a figure depicting a process example of determination (Step S22) of evaluation partial areas Si based on classification in the first embodiment.

FIG. 14 is a figure depicting an example of an evaluation partial area Si for each image quality evaluation value Ei in the first embodiment.

FIG. 15 is a figure depicting examples of classification criteria of classification segmentation areas in the first embodiment.

FIG. 16 is a figure depicting a process example and a GUI example of determination of internal parameters at Step S63 in the first embodiment.

FIG. 17 is a figure depicting data examples of internal parameters and element image quality evaluation values of image quality evaluation values Ei in the first embodiment.

FIG. 18 is a figure depicting a process example of calculation of image quality evaluation values by use of element image quality evaluation values in the first embodiment.

FIG. 19 is a figure depicting an example of a machine learning model used at Step S3 in the first embodiment.

FIG. 20 is a figure depicting a process example of Step S3 at which a comprehensive evaluation value C is calculated in the first embodiment.

FIG. 21 is a figure depicting a procedure including an image quality enhancement process and a functional block configuration in the first embodiment.

FIG. 22 is a figure depicting determination of parameters P of an image quality enhancement process by use of area target values in the first embodiment.

FIG. 23 is a figure depicting determination of parameters P of an image quality enhancement process by use of the comprehensive evaluation value C in the first embodiment.

FIG. 24 is a figure depicting determination of parameters P in a case where a rule-based image quality enhancement engine is used in the first embodiment.

FIG. 25 is a figure depicting determination of parameters P in a case where a machine-learning image quality enhancement engine is used in the first embodiment.

FIG. 26 is a figure depicting a GUI screen example related to an image quality enhancement process in the first embodiment.

FIG. 27 is a figure depicting a GUI screen example related to correction of evaluation partial areas in the first embodiment.

FIG. 28 is a figure depicting a procedure including such steps as correction of evaluation partial areas in the first embodiment.

FIG. 29 is a figure depicting a GUI screen example related to a step of benchmarking in the first embodiment.

FIG. 30 is a figure depicting a process example of a defect detection step in the first embodiment.

FIG. 31 is a figure depicting a process example of a shape measurement step in the first embodiment.

FIG. 32 is a figure depicting a procedure including an image capturing condition determination step using image quality evaluation values in the first embodiment.

FIG. 33 is a figure depicting a process example of an apparatus monitoring step using image quality evaluation values in the first embodiment.

### MODE FOR CARRYING OUT THE INVENTION

Hereinbelow, an embodiment of the present disclosure is explained in detail with reference to the figures. In the figures, identical sections are given identical reference symbols in principle, and repetitive explanation is omitted. In the figures, representations of constituent elements do not represent actual positions, sizes, shapes, ranges, and the like in some cases, in order to facilitate understanding of the invention.

For the purpose of explanation, when a process based on a program is explained, the process is explained with the program, a functionality, a processing section, or the like as the main subject in some cases, but the main subject as hardware therefor is a processor, or a controller, an apparatus, a computer, a system, or the like configured using the processor and the like. A computer executes processes in accordance with a program read out onto a memory, while causing a processor to use such resources as a memory and a communication interface as appropriate. Thus, predetermined functionalities, processing sections, and the like are realized. For example, a processor is configured using semiconductor devices such as a CPU/MPU or a GPU, or the like. Processes can be implemented not only by software program processing but also by a dedicated circuit. A dedicated circuit such as an FPGA, an ASIC, or a CPLD can be applied.

A program may be installed as data in advance on a target computer or may be distributed as data from a program source to a target computer. A program source may be a program distribution server on a communication network or may be a non-transitory computer-readable storage medium, for example, a memory card or a disc. A program may include a plurality of modules. A computer system may include a plurality of apparatuses. A computer system may be configured using a client-server system, a cloud computing system, an IoT system, or the like. For example, various types of data and information are configured using such structures as tables and lists but are not limited to these. Representations such as identification information, identifiers, IDs, names, and numbers are mutually interchangeable.

### First Embodiment

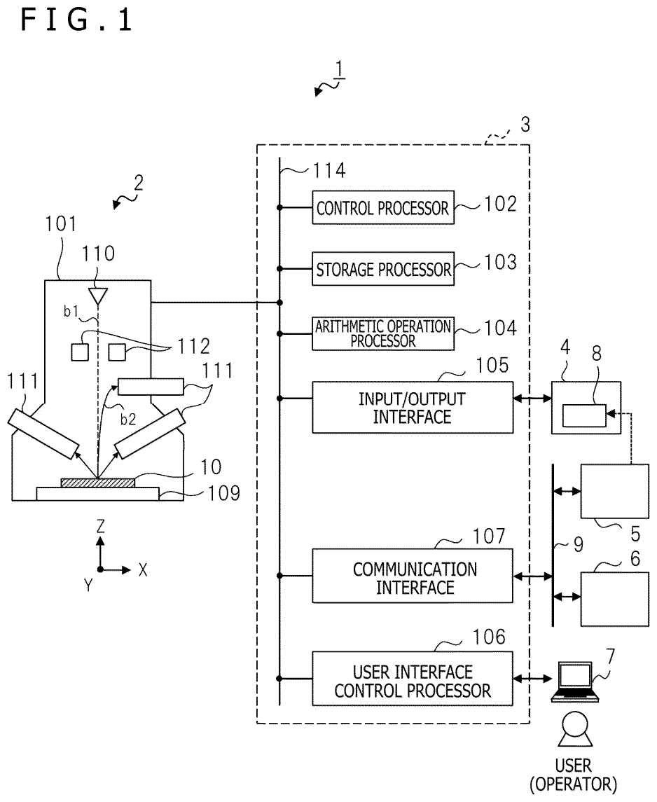

A sample observation apparatus and method of a first embodiment are explained using FIG. 1 to FIG. 33. The sample observation method of the first embodiment is a method having steps executed by the sample observation apparatus of the first embodiment. A sample observation apparatus 1 of the first embodiment depicted in FIG. 1 and the like is an apparatus having a functionality to observe a semiconductor wafer 10 which is a sample 10.

The sample observation apparatus 1 of the first embodiment captures images of the wafer 10, which is the sample 10, with use of an optical microscope, an SEM, or the like as a microscope or an image capturing device. In the case explained in the first embodiment, the sample observation apparatus 1 includes an SEM 2 (FIG. 1). The sample observation apparatus 1 of the first embodiment includes a computer system 3 (i.e., a controller or a control device) that controls the SEM 2. In the case explained in the first embodiment, the computer system 3 calculates image quality evaluation values Ei and the like.

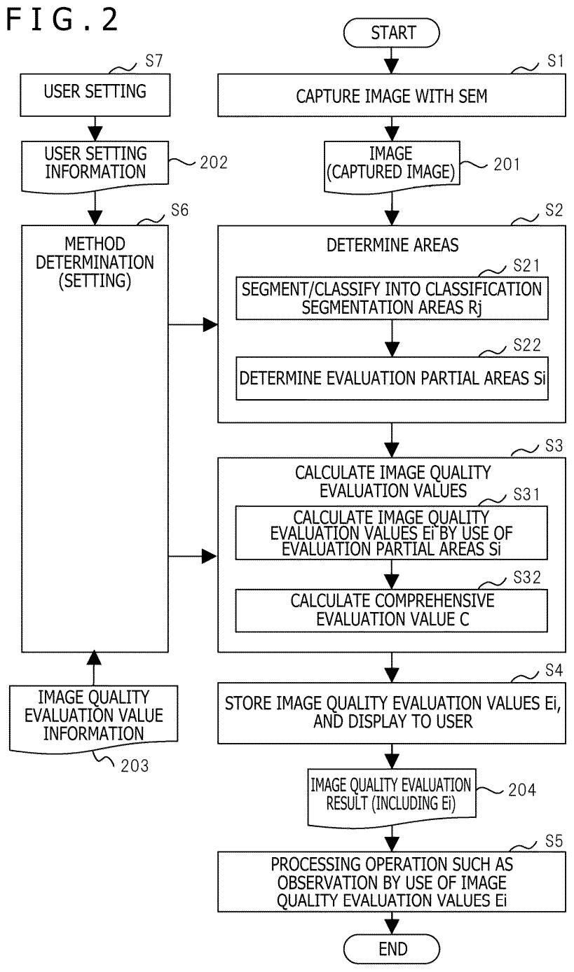

The computer system 3 of the sample observation apparatus 1 has an image capturing mechanism to control the SEM 2 to acquire images 201 (FIG. 2) which are captured images (i.e., observation images), and an observation mechanism to observe the images 201, for example, a defect detection mechanism to detect a defective site in an observation image. Each mechanism is realized by a control processor 102 (FIG. 1) and the like.

The sample observation method of the first embodiment depicted in FIG. 2 and the like has Step S1 of capturing images of the semiconductor wafer 10 which is the sample 10 with use of the SEM 2 (FIG. 1) to obtain images 201, and Step S5 of observing the semiconductor wafer 10 which is the sample 10 by use of the captured images 201. For the observation, the sample observation method of the first embodiment has Step S3 of calculating a plurality of image quality evaluation values Ei related to the captured images 201. The sample observation method of the first embodiment has Step S2 of determining evaluation partial areas Si for calculating the image quality evaluation values Ei from the respective images 201 captured with the SEM 2 (FIG. 1). Then, at Step S3 in the sample observation method of the first embodiment, the plurality of image quality evaluation values Ei are calculated as a plurality of elements of the quality of the images 201 by using the evaluation partial areas Si. On the basis of the image quality evaluation values Ei obtained as a result of Steps S2 and S3, it is possible to select, as an observation image, an image 201 suited for the observation (Step S5), that is, an image 201 with as high quality as possible, from the captured images 201.

In an exemplary case explained in the first embodiment, as the sample observation apparatus 1 and method, defects and the like of the semiconductor wafer 10 as the sample 10 are observed/detected. It is assumed that Step S5 in FIG. 2 is a step of performing an observation operation on the observation image as a predetermined processing operation, but operations to be performed are not limited to the observation operation. In addition, in the case explained in the first embodiment, the sample observation apparatus 1 refers to defect detection information 8 (including defect candidate coordinates mentioned before) generated and output by an external defect inspecting apparatus 5 (FIG. 1), and captures images 201 (FIG. 2) by using the defect candidate coordinates as an image capturing position.

In addition, in the example explained in the first embodiment, the SEM 2 (FIG. 1) is used as a microscope or an image capturing device used by the sample observation apparatus 1. This is not the sole example. As a microscope or an image capturing device, another type of microscope or image capturing device such as an optical microscope or a charged particle beam device that uses charged particles such as ions, for example, also can be applied. Processes in a system including the sample observation apparatus 1 are performed using images appropriate for the type of a microscope/image capturing device used and image capturing information (e.g., information concerning image capturing positions, image capturing magnification, and the like).

In addition, in the case explained in the first embodiment, as the images 201 (FIG. 2) captured with the SEM 2, basically, images captured in a direction perpendicular to a wafer upper surface as an image capturing direction, in other words, top view images, are used. This is not the sole example. As the images 201, images captured in a direction diagonal to the direction perpendicular to the wafer upper surface, in other words, a tilted direction or the like, also can be applied similarly.

### [Sample Observation Apparatus]

FIG. 1 depicts a configuration of the system including the sample observation apparatus 1 of the first embodiment. The sample observation apparatus 1 mainly has the SEM 2 (scanning electron microscope) and the computer system 3. The SEM 2 is an example of an image capturing device or a microscope and, in other words, is a charged particle beam device. The computer system 3 is a superior control apparatus, in other words, a controller, for the SEM 2. As a specific example, the sample observation apparatus 1 is a review SEM having the ADR functionality mentioned before. The SEM 2 is coupled with the computer system 3 through a connection wire (i.e., a signal line or a communication line) or the like. The computer system 3 is an apparatus having a functionality to control the SEM 2 and the like. The sample observation apparatus 1 has at least a functionality to control the SEM 2 to acquire images captured with the SEM 2 and a functionality to observe the sample 10 on the basis of the captured images.

The sample observation apparatus 1 includes necessary functional blocks and various devices, but the figure illustrates some of them including essential elements. The whole including the sample observation apparatus 1 in FIG. 1 is, in other words, configured as a semiconductor inspection system or the like.

A communication network 9 (e.g., a LAN) is connected with the defect inspecting apparatus 5, a defect classifying apparatus 6, and the like, for example, as apparatuses outside the sample observation apparatus 1. In the present example, the defect detection information 8 is created in advance as a result of inspection of a wafer which is the sample 10 at the external defect inspecting apparatus 5. The defect detection information 8 is information including defect candidate coordinates. The defect detection information 8 output from the defect inspecting apparatus 5 is stored, for example, on an external storage device 4 in advance. This is not the sole example. The defect detection information 8 may be stored on a database such as a server on the communication network 9 or the like. The computer system 3 reads out and refers to the defect detection information 8 from the external storage device 4 at the time of observation.

The defect classifying apparatus 6 is an apparatus or a system having the ADC functionality mentioned before. The defect classifying apparatus 6 performs an ADC process on the basis of data/information concerning processing results of observation by the ADR functionality at the sample observation apparatus 1, and obtains results of classification of defects and defect images. Note that not only the configuration example in FIG. 1 but also a form in which the defect classifying apparatus 6 is merged in the sample observation apparatus 1 is possible.

While FIG. 1 depicts a case where the superior control apparatus for the SEM 2 is configured using one computer system 3, the superior control apparatus may be configured using a plurality of computer systems, for example, a plurality of server apparatuses.

The computer system 3 includes the control processor 102, a storage processor 103, an arithmetic operation processor 104, an input/output interface 105, a communication interface 107, a user interface control processor 106, and the like. These constituent elements are connected to a bus 114, and mutual communication and input/output thereamong are possible.

The control processor 102 performs the overall control. For example, the control processor 102 has a hardware circuit or a processor such as a CPU, an MPU, or a GPU. In a case where the control processor 102 has such a processor as a CPU, the processor executes processes in accordance with a program read out from the storage processor 103. For example, the control processor 102 realizes various functionalities on the basis of program processing. For example, the arithmetic operation processor 104 has a processor such as a CPU, an MPU, or a GPU and a memory such as a ROM or a RAM. The arithmetic operation processor 104 performs arithmetic operation in accordance with a program read out from the storage processor 103 by the processor. Note that the control processor 102 and the arithmetic operation processor 104 may be configured integrally.

The storage processor 103 is configured using a device that stores various types of information and data including programs, and, for example, can be configured using a storage medium device including a magnetic disc, a semiconductor memory, or the like. The storage processor 103 may store data such as programs read in from the external storage device 4 or the communication network 9. The storage processor 103 may store the defect detection information 8 and the like read in from the external storage device 4 or the like. The storage processor 103 may store image data and the like acquired from the SEM 2.

The input/output interface 105 is a device on which an interface with an input device, an output device, and the external storage device 4 is implemented, and performs input/output of data and information with those devices. The computer system 3 is connected with, for example, the external storage device 4 through the input/output interface 105. The external storage device 4 may have stored thereon various types of programs and data. The external storage device 4 may store image data and processing result information.

The communication interface 107 is a device on which a communication interface corresponding to the communication network 9 such as a LAN is implemented, and transmits and receives data and information to and from the communication network 9. The computer system 3 is connected with the communication network 9 through the communication interface 107. The computer system 3 is connected with external systems and apparatuses via the communication network 9 and can communicate with them. For example, the communication network 9 is connected with the defect inspecting apparatus 5 and the defect classifying apparatus 6. Other examples of the external apparatuses include a database server, a manufacturing execution system (MES), and the like. The computer system 3 may refer to design data of samples (i.e., sample information) and information concerning manufacturing processes in the external apparatuses. Examples of the design data include CAD data and the like. Examples of the manufacturing processes include etching, deposition, and the like.

The user interface control processor 106 is a section where user interfaces including a graphical user interface (GUI) for allowing a user, in other words, an operator, to input information/data and for outputting information/data to the user are provided/controlled. The computer system 3 may be connected with a user terminal 7 (i.e., a client terminal) as an input/output terminal through the user interface control processor 106. The user terminal 7 may be an apparatus connected to the communication network 9. The user terminal 7 and other input/output devices may be sections integrally built in the computer system 3. The user interface control processor 106 provides the user terminal 7 with data of a screen (e.g., a Web page) corresponding to the GUI. The input/output interface 105 or the user interface control processor 106 may be connected with other input/output devices, for example, a display device, a sound output device, an operation device, and the like. The user interface control processor 106 may be integrated with the control processor 102 or the like.

The configuration of the computer system 3 in FIG. 1 is not the sole example, and there may be one or more computer systems. While the computer system 3 in FIG. 1 has a plurality of processors therein, it is sufficient if the configuration has at least one processor.

The user operates the user terminal 7 or another input/output device to input information concerning, for example, instructions and settings to the sample observation apparatus 1, in particular, to the computer system 3, and also checks information output on a screen, for example. For example, a typical PC may be applied as the user terminal 7. The user terminal 7 may have a built-in keyboard, mouse, display, and the like, or may be connected with an external keyboard, mouse, display, and the like. The user terminal 7 may be a remote terminal connected to the communication network 9 such as the Internet. The user interface control processor 106 creates data of a screen having a GUI thereon and provides the user terminal 7 with the data through communication, and the user terminal 7 displays the screen on its display.

The system including the sample observation apparatus 1 may have a form like the one below. The computer system 3 may be configured as a server in a client-server system, a cloud computing system, an IoT system, or the like. The user terminal 7 may be configured as a client computer for the server. In the case of the form of a client-server system, for example, the user operates the user terminal 7, which is a client computer, and the user terminal 7 transmits a request to the computer system 3, which is a server. The server receives the request and performs a process (e.g., an image capturing or observation process) according to the request. In response, the server transmits, to the user terminal 7, data of a screen (e.g., a Web page) including a requested processing result or the like. The user terminal 7 receives the response data and displays the screen (e.g., the Web page) on its display. The user can check the processing result and the like on the screen.

In addition, for example, machine learning may be performed for the computer system 3 or an external apparatus. A lot of computer resources are required for machine learning in some cases. In this case, processes related to machine learning may be performed in a server group such as a cloud computing system. In addition, functionalities may be allocated to a server group and a client computer. In a case where machine learning is performed, the computer system 3 trains a learning model by using training images and the like at a learning phase. By training, parameters of the learning model are adjusted. As the learning model, for example, a CNN (convolutional neural network) or the like can be applied. At an estimation phase, the computer system 3 inputs a target image to the trained learning model, and obtains determination result information or the like as an output which is a result of estimation by the learning model. Note that a business operator and a computer system that implement learning/training of the model at the learning phase and a business operator and a computer system that implement estimation using the trained model at the estimation phase may be separate entities.

### [SEM]

In FIG. 1, the SEM 2 includes, in a housing 101, a stage 109, an electron gun 110, an unillustrated electronic lens, a deflector 112, a detector 111, and the like. The stage 109 is, in other words, a sample stage, on which a semiconductor wafer which is the sample 10 is placed and held. The stage 109 is a mechanism that can move, rotate, incline, and so on in horizontal directions (in an X-direction and a Y-direction illustrated), a vertical direction (Z-direction), and the like. The electron gun 110 irradiates the sample 10 on the stage 109 with an electron beam b1, in other words, with a charged particle beam b1. The unillustrated electronic lens converges the electron beam b1 onto a surface of the sample 10. The deflector 112 scans the surface of the sample 10 with the electron beam b1. The detector 111 detects, as an electric signal, electrons/particles b2 such as secondary electrons or backscattered electrons generated from the sample 10 due to the irradiation with the electron beam b1. In other words, the detector 111 detects, as an image, a state of the surface of the sample 10. In the present example, the detector 111 has a plurality of detectors at a plurality of positions.

In the present example, the SEM control functionality of the computer system 3 controls such elements as the stage 109, the electron gun 110, the deflector 112, the detector 111, and the like of the SEM 2. Note that illustrations of such elements as a drive circuit for driving mechanisms including the stage 109 and the like are omitted.

The SEM 2 captures images of the wafer 10, which is the sample 10, in accordance with set image capturing conditions on the basis of control by the computer system 3 or the like. An image signal detected as an electric signal by the detector 111 of the SEM 2 is supplied to the computer system 3 through a connection wire. Note that there may be a circuit such as an analog/digital conversion circuit inside or downstream of the detector 111. The computer system 3 acquires images (images 201 in FIG. 2) by causing the control processor 102, the arithmetic operation processor 104, or the like to process image signals supplied from the detector 111. Note that, at the time of image capturing with the SEM 2, the plurality of detectors 111 included in the SEM 2 may acquire a plurality of images. The computer system 3 may generate images 201 by performing a process using the plurality of acquired images. The computer system 3 stores data/information concerning the images and the like on the storage processor 103 or the like. The computer system 3 performs an observation process on the images, determines/detects, for example, defective sites, and stores processing result information on the storage processor 103 or the like.

The sample observation apparatus 1 in FIG. 1 includes the SEM 2 that captures images of the sample 10 on the basis of defect candidate coordinates in the defect detection information 8 from the defect inspecting apparatus 5. Alternatively, the sample observation apparatus 1 may perform similar operations by using an external microscope or an external image capturing device. The computer system 3 may control the external microscope or image capturing device, acquire captured images from the external microscope or image capturing device, and so on. In the present system, a plurality of types of microscope or image capturing device, for example, an SEM and an optical microscope, may be mixedly present. The computer system 3 may select a microscope or an image capturing device to use, as appropriate on a case-by-case basis. The whole of a system like the one in FIG. 1 is not limited to a configuration formed by the single sample observation apparatus 1, and may include one or more microscopes/image capturing devices that capture images of the sample 10 and one or more computer systems or sample observation apparatuses that perform processes such as observation of captured images.

### [Basic Processing Procedure]

The sample observation apparatus 1 and method of the first embodiment are explained using FIG. 2. FIG. 2 depicts a basic processing procedure executed by the computer system 3 (FIG. 1) in the sample observation apparatus 1 and method of the first embodiment, and depicts Steps S1 to S7. The sample observation method of the first embodiment is a method for observing the sample 10 and has Steps S2 and S3 for calculating image quality evaluation values Ei. The computer system 3 in the sample observation apparatus 1 of the first embodiment performs a process of calculating the image quality evaluation values Ei, and the like. The processing procedure in FIG. 2 corresponds also to the basic functional block configuration related to functionalities of the computer system 3 in FIG. 1.

### [Calculation of Image Quality Evaluation Values of Observation Image]

An implementation example related to calculation of image quality evaluation values Ei in the sample observation apparatus 1 and method of the first embodiment is explained with reference to FIG. 2. In FIG. 2, one of features of the sample observation method of the first embodiment is that the sample observation method includes an area determination step (Step S2) of determining evaluation partial areas Si in an image 201 (also referred to as an SEM image) captured of the semiconductor wafer 10, which is the sample 10, with the SEM 2, and an image quality evaluation value calculation step (Step S3) of calculating image quality evaluation values Ei which differ between different evaluation partial areas Si.

There is a problem related to calculation of image quality evaluation values of an SEM image as follows. Image features related to image quality evaluation values of an SEM image are present in particular areas in the SEM image in many cases. Hence, in a case where the SEM image as a whole is treated as a calculation area of the image quality evaluation values, image features of an area that is not related to or is less related to image quality evaluation values also influence the image quality evaluation values which are calculation results. For example, in a case where sharpness is evaluated as a quality item of the SEM image, it is desired to evaluate only the amount of change in brightness near edges of a circuit pattern of a wafer. If the SEM image as a whole is set as a calculation area, noise generated in a flat section of the circuit pattern influences an image quality evaluation value, that is, sharpness, undesirably.

In view of this, in the sample observation apparatus and method of the first embodiment, in a case where there are a plurality of image quality evaluation values Ei (i.e., parameter values or evaluation item values) as elements included in the image quality of a captured image 201, for each image quality evaluation value Ei, a particular area suited for calculation of the image quality evaluation value Ei is determined as an evaluation partial area Si (Step S2). Then, in the sample observation apparatus and method of the first embodiment, the image quality evaluation value Ei is calculated using the evaluation partial area Si (Step S3).

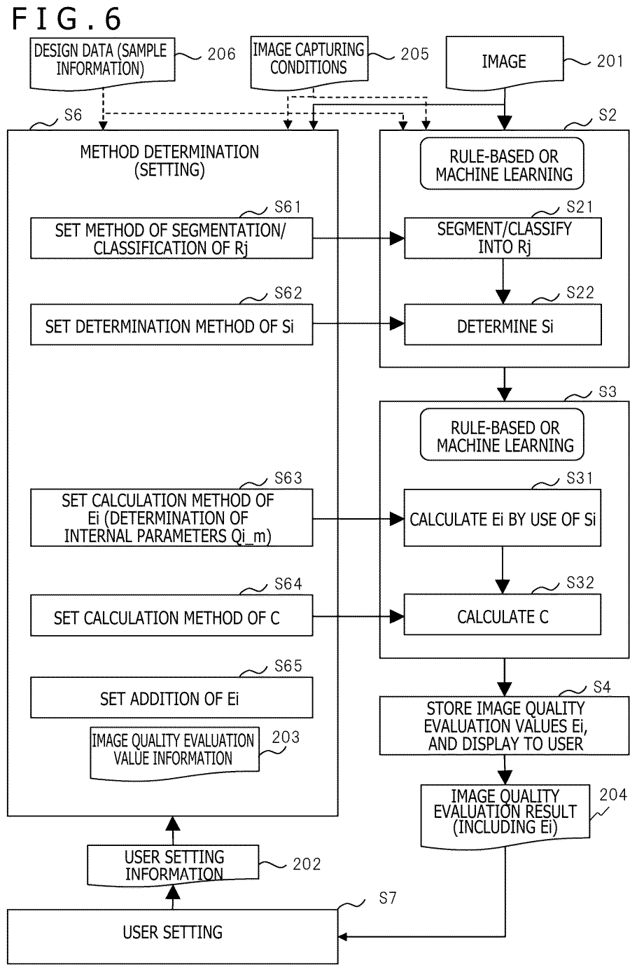

In FIG. 2, first, at Step S1, which is an image capturing Step, the computer system 3 controls image capturing with the SEM 2 to acquire images 201 (i.e., captured images, target images, SEM images, etc.) for observation of the wafer 10, which is the sample 10. Note that, at this time, the images 201 are captured using image capturing conditions 205 (FIG. 6) mentioned later and the like.

Next, at Step S2, which is an area determination step, the computer system 3 performs an area determination process on the captured images 201 to determine an evaluation partial area Si (i=1 to N, N: the number of partial areas) for each image quality evaluation value Ei of the plurality of image quality evaluation values Ei applied to the images 201. At Step S2, in addition to the images 201, the image capturing conditions 205 and design data 206 (FIG. 6) mentioned later, manufacturing process information, and the like may be used as input information.

Next, at Step S3, which is an image quality evaluation value calculation step, using the evaluation partial areas Si obtained at Step S2 and corresponding to the respective image quality evaluation values Ei applied to the images 201, the computer system 3 calculates the respective image quality evaluation values Ei (i=1 to N, N: the number of image quality evaluation values) which differ between the different evaluation partial areas Si.

Next, at Step S4, the computer system 3 stores, on a memory resource (e.g., the storage processor 103 in FIG. 1), the image quality evaluation values Ei calculated at Step S3, and also displays the image quality evaluation values Ei to the user (FIG. 1). Examples of this displaying include causing the user interface control processor 106 in FIG. 1 to provide the user of the user terminal 7 with a GUI screen (mentioned later) including such information as the image quality evaluation values Ei. The user can check the image quality evaluation values Ei and the like on the screen. Results of Step S4 are output as an image quality evaluation result 204 including the image quality evaluation values Ei.

Next, at Step S5, using the image quality evaluation result 204 including the image quality evaluation values Ei calculated at Step S3 described above, the computer system 3 performs a predetermined processing operation such as observation, and generates and stores processing result information. In one example, in the case of an observation operation, the computer system 3 selects, as an observation image, an image 201 judged as having high image quality on the basis of the image quality evaluation values Ei, and performs the observation operation. After Step S5, this procedure ends.

In addition, Step S6 is a step of determining methods of, in other words, setting values of, the processing operations related to Step S2 and Step S3, and, in other words, is a setting step or a method determination step. This Step S6 includes determination/setting concerning a method of determining evaluation partial areas Si at Step S2 and a method of calculating image quality evaluation values Ei at Step S3. At Step S6, the computer system 3 determines the methods and setting values on the basis of user setting information 202. Regarding the processes of respective steps (S21, S22, S31, and S32), the computer system 3 determines control parameter values and the like in methods selected from several methods, and apply the control parameter values and the like to the processes at the respective steps as setting values. Contents of the determination at Step S6 may be set as the design of the present system in advance or may be determined in accordance with the user setting information 202 set by the user.

In a case where the user setting information 202 is used, at Step S7, setting by the user (FIG. 1) such as selection of a method and control parameter values to be applied, for example, is performed in advance on a GUI screen provided by the computer system 3, and the user setting information 202 is stored on a memory resource. Step S6 and Step S7 may be integrated into one step.

At Step S6, as in Step S2, using a target image 201 as well as image capturing conditions 204, design data 205, and the like (FIG. 6) mentioned later as inputs, the computer system 3 may determine a method and setting values of each step. Step S6 may be performed before execution of Step S2 and Step S3 or may be performed after the user checks execution results of Step S2 and Step S3.

Details of the procedure in FIG. 2 are as follows. Step S2 specifically includes two steps, Step S21 and Step S22. Step S21 is a segmentation/classification step of generating classification segmentation areas Rj obtained by segmenting an image 201 and classifying segmented areas. Step S22 is an evaluation partial area determination step of determining evaluation partial areas Si by using the classification segmentation areas Rj, which are classification results.

Step S3 specifically includes two steps, Step S31 and Step S32. Step S31 is a step of calculating an image quality evaluation value Ei for each evaluation partial area Si by using the evaluation partial areas Si. Step S32 is a step of calculating a comprehensive evaluation value C as a combination of a plurality of image quality evaluation values Ei.

At Step S2, the evaluation partial areas Si may be calculated using rule-based image processing or may be calculated using machine learning. In addition, at Step S3, the image quality evaluation values Ei may be calculated using rule-based image processing or may be calculated using machine learning.

### [Image Quality Items Evaluated Using Image Quality Evaluation Values Ei (1)]

Image quality evaluation values Ei and image quality items evaluated using the image quality evaluation values Ei are explained. In the first embodiment of the present disclosure, there are a plurality of different image quality items that are related to an image 201 captured with the SEM 2 and are evaluated using a plurality of different image quality evaluation values Ei. Examples of the image quality evaluation values Ei and the image quality items, in other words, image quality elements, evaluation items, and parameter values, include the following.

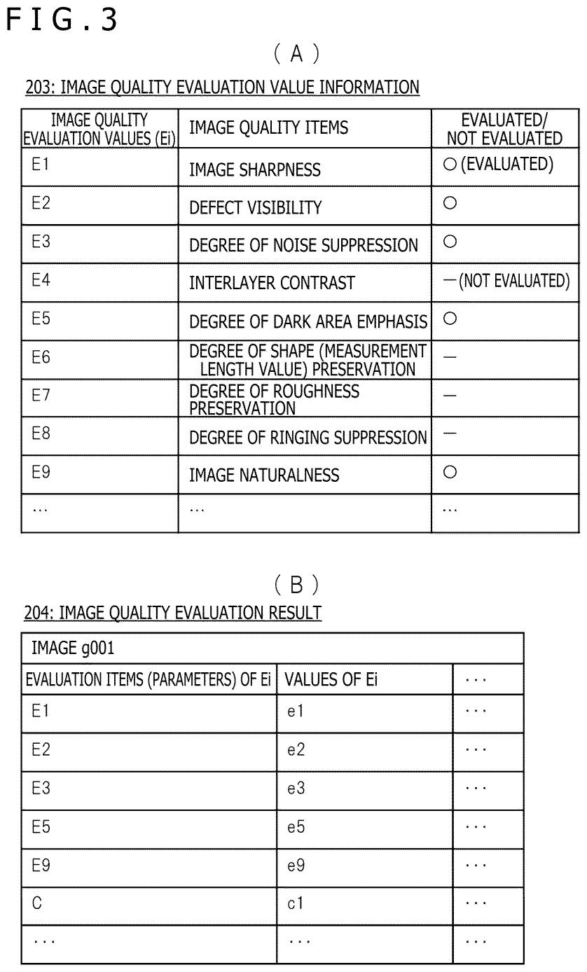

(A) in FIG. 3 depicts, in a tabular format, image quality evaluation value information 203 which is setting information/data of image quality evaluation values Ei and image quality items. The computer system 3 retains, in advance in a memory resource, the image quality evaluation value information 203 on the basis of settings. FIG. 2 depicts that the image quality evaluation value information 203 is used at Step S6 of setting. The image quality evaluation value information 203 may be set at Step S7 of user setting. The image quality evaluation value information 203 thus set is referred to at Step S2 or S3.

The table of the image quality evaluation value information 203 in (A) in FIG. 3 has columns “image quality evaluation values (Ei),” “image quality items,” and “evaluated/not evaluated.” The “image quality evaluation values (Ei)” column represents identification information concerning image quality evaluation values. The “image quality items” column represents image quality items corresponding to the image quality evaluation values Ei and evaluated by the image quality evaluation values Ei, and, in other words, represents image quality names and image quality explanation. The “evaluated/not evaluated” column represents whether the image quality items of a target image 201 according to the image quality evaluation values Ei of the respective rows are to be evaluated or not evaluated, and, in other words, represents whether or not the evaluation items/parameters are applied. Circles represent that the image quality items are “evaluated” (applied).

It is possible to set “evaluated/not evaluated” as appropriate for each image quality evaluation value Ei depending on a target image 201 (FIG. 2). The user may be allowed to perform this setting on a GUI screen (Step S7 of user setting in FIG. 2). Alternatively, the present system may automatically make the determination (Step S6). For example, the computer system 3 may automatically select image quality evaluation values Ei used at past steps (a manufacturing process of semiconductor devices) handling a pattern similar to a semiconductor pattern seen in the image 201, and apply the image quality evaluation values Ei to the image 201. The computer system 3 may also refer to manufacturing process information related to the sample 10, past record information, statistical information, and the like as appropriate.

Note that (A) in FIG. 3 depicts only parameters of the image quality evaluation values Ei for explanation, and parameter values to be specifically calculated are stored on a memory resource as appropriate in association with a target image 201. (B) in FIG. 3 depicts, in a tabular format, a data example of the image quality evaluation result 204 (FIG. 2). In this image quality evaluation result 204, parameters (evaluation items) and values of the image quality evaluation values Ei are stored for each target image 201. For example, the parameters include E1 to E9 similar to those in (A) and the comprehensive evaluation value C calculated at Step S32.

In the first embodiment, two or more of the plurality of image quality evaluation values Ei described above are used for each image 201 (FIG. 2) or for each set predetermined target (e.g., the same semiconductor wafer 10). The example in FIG. 3 depicts a case of such setting that respective image quality items are evaluated using the image quality evaluation values E1, E2, E3, E5, and E9 for a certain image 201.

In the example in (A) in FIG. 3, as the plurality of image quality evaluation values Ei, there are nine types of parameter values E1 to E9 listed below.
(E1): image sharpness
(E2): defect visibility
(E3): degree of noise suppression
(E4): interlayer contrast
(E5): degree of dark area emphasis
(E6): degree of shape preservation (degree of measurement length value preservation)
(E7): degree of roughness preservation
(E8): degree of ringing suppression
(E9): image naturalness

A summary of each image quality evaluation value Ei and the image quality item evaluated using it is as follows.

(E1) image sharpness represents the ease of distinguishing areas with different structures or materials from each other, and typically is calculated as the degree of change in brightness at a boundary (edge) between areas with different structures or materials.

(E2) defect visibility represents the ease of distinguishing a defective area from a surrounding area, and includes, for example, contrast between a defective area and a surrounding area, contrast inside a defective area, intensity of shadow caused by a defect, and the like.

(E3) degree of noise suppression represents how less noise generated due to image capturing or the like is.

(E4) interlayer contrast represents contrast between different layers in a semiconductor pattern.

(E5) degree of dark area emphasis represents contrast in a dark area such as a lower layer of a semiconductor pattern, or contrast between a dark area and a defective area.

(E6) degree of shape preservation (in other words, degree of measurement length preservation) represents the degree of similarity between a measurement length value in a reference image having captured therein a similar pattern and a measurement length value in an evaluation target image. The greater this evaluation value is, the more preserved the shape of a pattern of a sample is.

(E7) degree of roughness preservation represents the degree of similarity between roughness of a pattern in a reference image having captured therein a similar pattern and roughness of a pattern in an evaluation target image. The greater this evaluation value is, the more preserved the roughness of a pattern of a sample is.

(E8) degree of ringing suppression represents how less ringing (which means wavy artifacts) generated in an image is.

(E9) image naturalness represents how less the sense of discomfort felt by a human when she/he sees an image is.

### [Image Quality Items Evaluated Using Image Quality Evaluation Values Ei (2)]

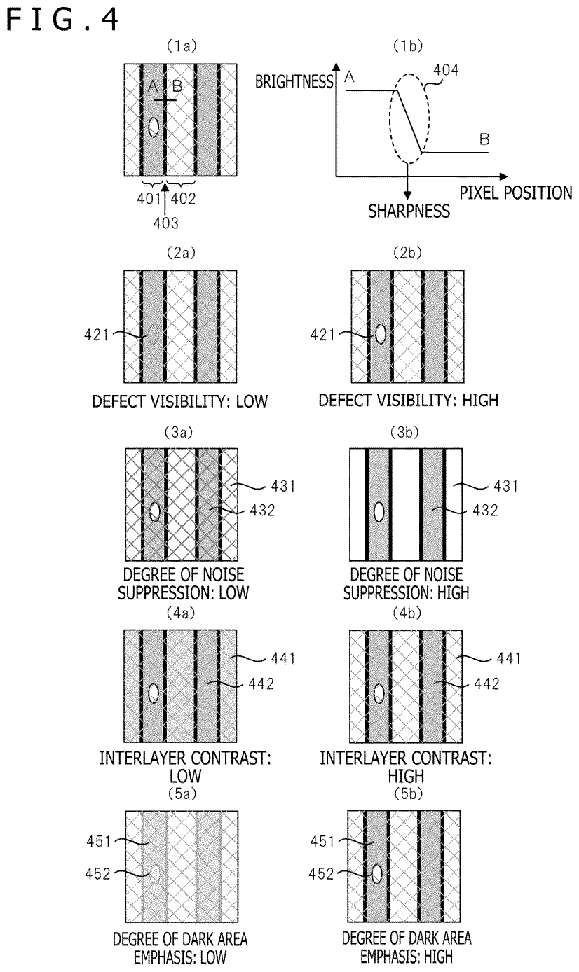

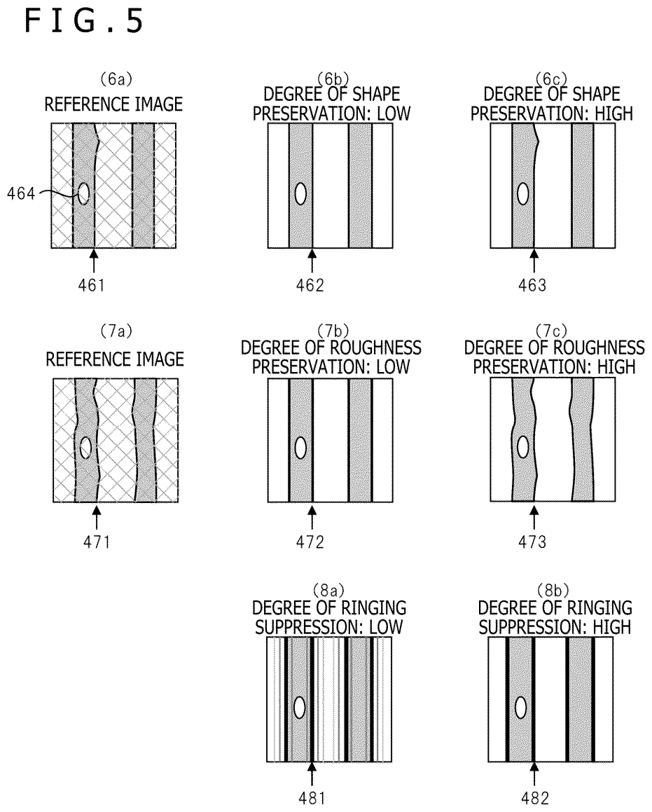

The definitions of the respective image quality evaluation values Ei in FIG. 3 are additionally explained. FIG. 4 and FIG. 5 are schematic explanatory diagrams representing the definition of each image quality evaluation value Ei.

(1) (1a) and (1b) in FIG. 4 are diagrams for explaining “sharpness” as the image quality evaluation value E1. (1a) depicts an example of an image, and (1b) depicts a brightness profile along a line A-B in the image. The line A-B is a line traversing a boundary (edge) 403 between certain vertical line pattern areas 401 and 402. As the value of sharpness, for example, the computer system 3 calculates a gradient 404 of the brightness profile at the boundary 403 between the pattern areas.

(2) (2a) and (2b) in FIG. 4 are diagrams for explaining “defect visibility” as the image quality evaluation value E2. An image of (2a) is an example of an image in a case where the defect visibility is relatively low, and an image of (2b) is an example of an image in a case where the defect visibility is relatively high. As the value of the defect visibility, for example, the computer system 3 calculates the contrast between a defective area 421 and a surrounding area of the defective area 421.

(3) (3a) and (3b) in FIG. 4 are diagrams for explaining “degree of noise suppression” as the image quality evaluation value E3. An image of (3a) is an example of an image in a case where the degree of noise suppression is relatively low, and an image of (3b) is an example of an image in a case where the degree of noise suppression is relatively high. As the value of the degree of noise suppression, for example, the computer system 3 calculates the amount of noise generated in a wiring upper surface area 431 and a dark area 432. The smaller the noise amount is, the higher the degree of noise suppression is.

(4) (4a) and (4b) in FIG. 4 are diagrams for explaining “interlayer contrast” as the image quality evaluation value E4. An image of (4a) is an example of an image in a case where the interlayer contrast is relatively low, and an image of (4b) is an example of an image in a case where the interlayer contrast is relatively high. As the value of the interlayer contrast, for example, the computer system 3 calculates a difference in average brightness between a wiring upper surface area 441 and a dark area (lower layer area) 442. The greater the brightness difference is, the higher the interlayer contrast is.

(5) (5a) and (5b) in FIG. 4 are diagrams for explaining “degree of dark area emphasis” as the image quality evaluation value E5. An image of (5a) is an example of an image in a case where the degree of dark area emphasis is relatively low, and an image of (5b) is an example of an image in a case where the degree of dark area emphasis is relatively high. As the value of the degree of dark area emphasis, for example, the computer system 3 calculates the contrast in a dark area 451 or the contrast between the dark area 451 and a defective area 452.

(6) (6a), (6b), and (6c) in FIG. 5 are diagrams for explaining “degree of shape preservation” as the image quality evaluation value E6, and depict examples of images. An image of (6a) is an example of a reference image, an image of (6b) is an example of an image in a case where the degree of shape preservation is relatively low, and an image of (6c) is an example of an image in a case where the degree of shape preservation is relatively high. The degree of shape preservation is a value for evaluating whether the shape of a pattern captured in the reference image is preserved also in an observation image as a quality evaluation target. The evaluation value can be calculated by comparison between an edge in the reference image and an edge in the evaluation target image. For example, a certain edge 461 in the reference image of (6a) and a corresponding edge 462 in the image of (6b) are compared with each other. In addition, the certain edge 461 in the reference image of (6a) and a corresponding edge 463 in the image of (6c) are compared with each other. A shape change of the edge 462 is relatively large in the image of (6b) as compared to the edge 461, whereas a shape change of the edge 463 is relatively small in the image of (6c) as compared to the edge 461.

While the shape of a wiring pattern changes in the present example, in calculation of the degree of shape preservation, not only the shape of a wiring pattern but also the shape of a defect (defective area 464) is evaluated as to whether the shape can be preserved. The shape of part of a pattern is not preserved in the case depicted in the present example. Also in a case where the shape of an edge does not change but the overall width of a pattern is reduced, the position of the edge changes, and as a result, the measurement length value of the pattern width changes, and the degree of shape preservation lowers.

(7) (7a), (7b), and (7c) in FIG. 5 are diagrams for explaining “degree of roughness preservation” as the image quality evaluation value E7, and depict examples of images. An image of (7a) is an example of a reference image, an image of (7b) is an example of an image in a case where the degree of roughness preservation is relatively low, and an image of (7c) is an example of an image in a case where the degree of roughness preservation is relatively high. A pattern of a semiconductor experiences fluctuations in the shape of an edge of the pattern in the course of manufacture. As the value of the degree of roughness preservation, the computer system 3 evaluates whether the roughness of an edge of a pattern captured in the reference image is preserved also in an observation image as a quality evaluation target. In the present example, an edge 471 of a certain pattern in the reference image of (7a) has fluctuations, i.e., roughness. In contrast, in the image of (7b), a corresponding edge 472 is close to a straight line, and, in the image of (7c), a corresponding edge 473 has fluctuations, i.e., roughness.

(8) (8a) and (8b) in FIG. 5 are diagrams for explaining “degree of ringing suppression” as the image quality evaluation value E8, and depict examples of images. An image of (8a) is an example of an image in a case where the degree of ringing suppression is relatively low, and an image of (8b) is an example of an image in a case where the degree of ringing suppression is relatively high. Due to the influence of image capturing conditions or image quality enhancement processes, wavy artifacts (called ringing) appear around an edge of a pattern of a sample in an observation image. The computer system 3 evaluates whether or not ringing has appeared in an evaluation target image, as the value of the degree of ringing suppression. At this time, as with the degree of shape preservation and degree of roughness preservation described above, the computer system 3 prepares a reference image and detects a change in brightness which has not been seen in the reference image, for example, so that the degree of ringing suppression can be calculated. In the image of (8a), for example, ringing (represented by a plurality of vertical lines) in a traverse direction is observed around a certain edge 481. In contrast, in the image of (8b), ringing is suppressed around a corresponding edge 482.

(9) “Image naturalness” as the image quality evaluation value E9 represents how less the sense of discomfort felt by a human when she/he sees an image is. For example, although the amount may vary, noise is generated in a typical observation image, and accordingly, there is a possibility that the image naturalness decreases in an image from which noise has completely been removed.

### [Setting Step (S6)]

Details of Step S6 of setting (method determination) are explained using FIG. 6. For example, as depicted in FIG. 6, Step S6 specifically has five steps, namely, Steps S61, S62, S63, S64, and S65.

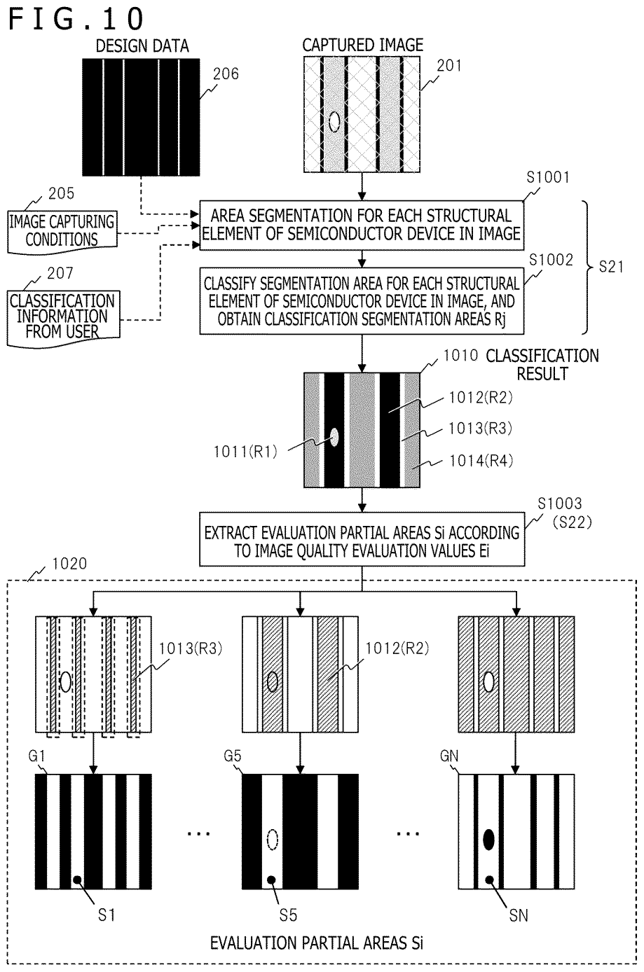

At Step S61, the computer system 3 sets a classification method of classification segmentation areas Rj to be used at Step S21 in FIG. 2. At Step S61, for example, the computer system 3 sets the classification method of classification segmentation areas Rj depicted in FIG. 10 and the like mentioned later.

At Step S62, the computer system 3 sets a determination method of evaluation partial areas Si to be used at Step S22 in FIG. 2.

Mainly, a rule-based method or a machine learning method can be set as the methods of Steps S21 and S22.

At Step S63, the computer system 3 determines a calculation method of image quality evaluation values Ei to be used at Step S31 in FIG. 2.

At Step S64, the computer system 3 determines a calculation method of the comprehensive evaluation value C to be used at Step S32 in FIG. 2.

Mainly, a rule-based method or a machine learning method can be set as the methods of Steps S31 and S32.

In addition to the respective steps described above, Step S65 may also be used. Image quality items evaluated using image quality evaluation values Ei are not limited to the nine types, the image quality evaluation values E1 to E9, mentioned with reference to FIG. 3, and new image quality evaluation values can be defined and added. In this case, at Step S65, the computer system 3 adds new image quality evaluation values Ei depending on the necessity of the user. For example, the computer system 3 adds the new image quality evaluation values Ei according to operation by the user on a GUI screen, and sets information concerning the added image quality evaluation values Ei in the image quality evaluation value information 203. More specifically, the added image quality evaluation values Ei are equivalent to a calculation method, definition information, a program, and the like for calculating the image quality evaluation values Ei. The added image quality evaluation values Ei then become candidates of image quality evaluation values Ei to be applied to an image 201, and “evaluated/not evaluated” in FIG. 3 can be selected for the added image quality evaluation values Ei. In addition, the added image quality evaluation values Ei may be variations of the image quality evaluation values E1 to E9 in FIG. 3. For example, in a case where an alternative calculation formula or the like can be used in the definition for calculating a certain image quality evaluation value Ei, the alternative calculation formula or the like may be set as a variation. For example, two types of image quality evaluation values Eia and Eib including the addition are set.

Examples of the image capturing conditions 205 include an acceleration voltage, a probe current, a beam opening angle, a beam tilt angle, a focal position, and the like, as various parameter values at the time of image capturing with the SEM 2 (FIG. 1). Examples of the design data 206, in other words, examples of sample information, include information concerning the shape of the semiconductor wafer 10, which is the sample 10 (FIG. 1), in particular, the height that varies depending on the horizontal position, information concerning the material, and the like.

### [Determination of Evaluation Partial Areas Si and Calculation of Image Quality Evaluation Values Ei]

There has been a problem related to image quality evaluation that, in a case where an image as a whole is treated as a calculation area of image quality evaluation values, image features of areas not related to the image quality also influence the image quality evaluation values, and accordingly, the image quality cannot be quantified, the quantification is difficult, or the quality of the quantification lowers.

In this regard, in the first embodiment, only areas having captured therein image features related to image quality evaluation values Ei corresponding to image quality items that are desired to be evaluated are determined as evaluation partial areas Si in a target image 201 (FIG. 2) (Step S2). Thus, it becomes possible to calculate the image quality evaluation values Ei by using the evaluation partial areas Si suited for the respective image quality items, and image quality quantification taking into consideration a plurality of the image quality items becomes possible.

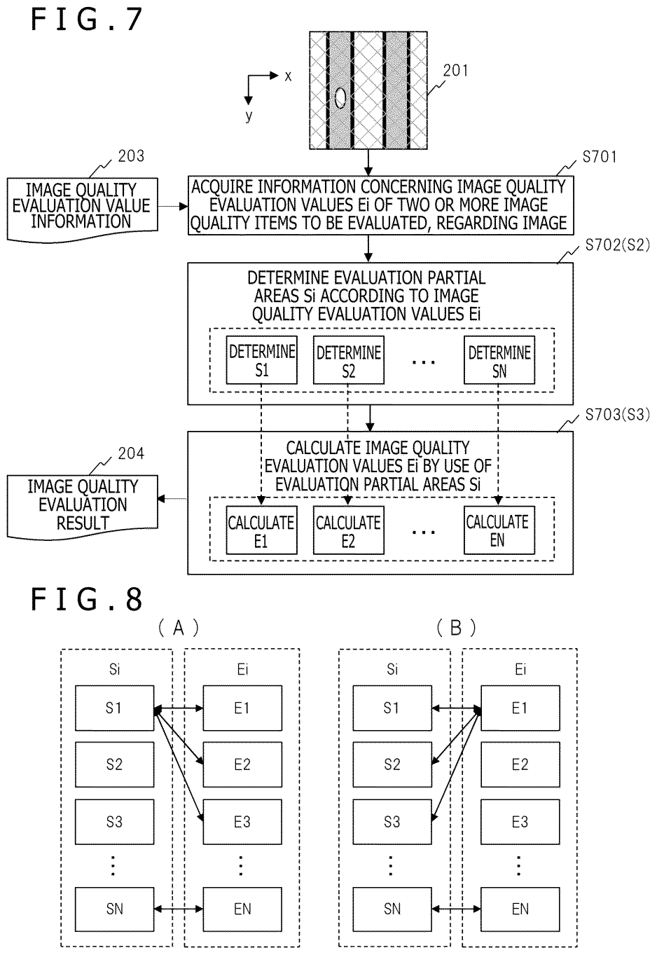

FIG. 7 depicts process examples of determination of evaluation partial areas Si and calculation of image quality evaluation values Ei corresponding to Steps S2 and S3 in FIG. 2. At Step S701, the computer system 3 acquires/refers to information concerning image quality evaluation values Ei of two or more image quality items to be applied to image quality evaluation of an input target image 201, from the image quality evaluation value information 203 like the one depicted in FIG. 3. Here, a plurality (N) of image quality evaluation values Ei to be applied are denoted as E1 to EN.

Next, at Step S702 corresponding to Step S2, the computer system 3 determines a plurality (N) of evaluation partial areas Si (S1 to SN) corresponding to the plurality (N) of image quality evaluation values Ei (E1 to EN) to be applied. That is, the computer system 3 determines an evaluation partial area Si for each image quality evaluation value Ei. Here, the plurality (N) of evaluation partial areas Si are denoted as S1 to SN.

In the present example, as depicted in FIG. 7, the correspondence between the plurality of image quality evaluation values Ei and the plurality of evaluation partial areas Si is one-to-one correspondence. The evaluation partial areas Si are one or more areas, and i=1 to N. N is the number of partial areas. The image quality evaluation values Ei are one or more parameter values, and i=1 to N. N is the number of parameters of evaluation items. While the number N of the evaluation partial areas Si and the number N of parameters of the image quality evaluation values Ei are the same in the present example, this is not the sole example.

Next, at Step S703 corresponding to Step S3, the computer system 3 calculates an image quality evaluation value Ei for each evaluation partial area Si. Calculation results are stored as the image quality evaluation result 204.

FIG. 8 depicts examples of cases where the correspondence between evaluation partial areas Si and image quality evaluation values Ei is not one-to-one correspondence, as modification examples. Either type of correspondence is possible. (A) depicts a case where the correspondence between Si and Ei includes one-to-many correspondence. For example, the image quality evaluation values E1, E2, and E3 are calculated using the evaluation partial area S1. (B) depicts a case where the correspondence between Si and Ei includes many-to-one correspondence. For example, the image quality evaluation value E1 is calculated using the evaluation partial areas S1, S2, and S3.

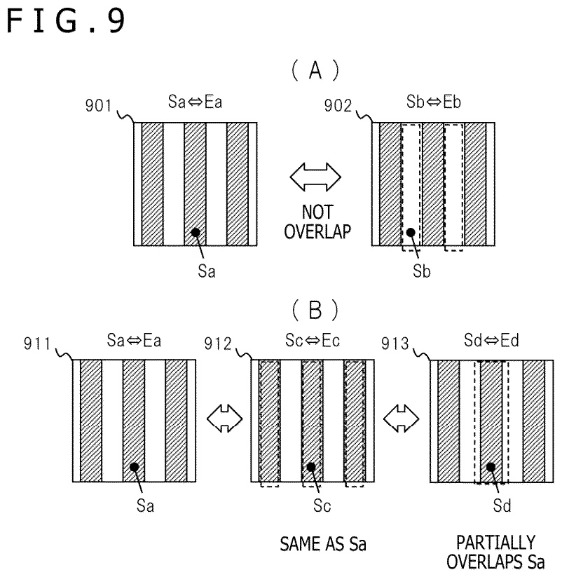

In addition, FIG. 9 is an explanatory diagram depicting a case where evaluation partial areas Si for respective image quality evaluation values Ei do not overlap and a case where evaluation partial areas Si for respective image quality evaluation values Ei overlap. There are a case where respective evaluation partial areas Si do not overlap and a case where respective evaluation partial areas Si overlap, and either case can be applied. An example in (A) depicts a case where an evaluation partial area Sa of a certain image quality evaluation value Ea and an evaluation partial area Sb of a certain image quality evaluation value Eb do not overlap. In the present example, a diagonal line pattern area in an image 901 is the evaluation partial area Sa, and a white area in an image 902 is the evaluation partial area Sb. These areas do not overlap.

An example in (B) depicts a case where the evaluation partial area Sa of the certain image quality evaluation value Ea and an evaluation partial area Sc of a certain image quality evaluation value Ec overlap and are the same, and a case where the evaluation partial area Sa of the certain image quality evaluation value Ea and an evaluation partial area Sd of a certain image quality evaluation value Ed partially overlap. In the present example, a diagonal line pattern area in an image 911 is the evaluation partial area Sa, and a diagonal line pattern area in an image 912 is the evaluation partial area Sb. These are the same. In addition, an area represented by a broken line frame in an image 913 is the evaluation partial area Sd, and the evaluation partial area Sd partially overlaps the evaluation partial area Sa. For example, the evaluation partial area Sd is an area formed by enlarging the horizontal width of the evaluation partial area Sa.

In the determination of evaluation partial areas Si (Step S22 in FIG. 2), different image quality evaluation values Ei, for example, E1 and E2, are the values of evaluation items (parameters) of different image quality items. Accordingly, basically, evaluation partial areas Si (e.g., S1 and S2) which are areas for calculating the image quality evaluation values Ei are also different areas in many cases. For example, the evaluation partial area Sa for the certain image quality evaluation value Ea and the evaluation partial area Sb for the other certain image quality evaluation value Eb do not overlap and are different areas as in the example depicted in (A) in FIG. 9. This is not the sole example. There may be a case where evaluation partial areas Si associated with respective image quality evaluation values Ei are the same or a case where evaluation partial areas Si associated with respective image quality evaluation values Ei partially overlap, as depicted in the example in (B) in FIG. 9.

### [Area Determination Step (S2)]

Details of Step S2 of determining areas in FIG. 2 are explained. At Step S21, the computer system 3 performs classification by classification segmentation areas Rj (j=1 to Nr) obtained by segmenting an image 201. Here, the classification segmentation areas are denoted by Rj, and j=1 to Nr. Nr is the number of segmentation areas. At Step S22, the computer system 3 determines evaluation partial areas Si (S1 to SN) on the basis of the classification segmentation areas Rj and classification results thereof.

There is a problem related to image quality evaluation that, in a case where image quality evaluation values (Ei) paying attention to structures of a semiconductor device are calculated as in the examples of sharpness (E1) and defect visibility (E2) in FIG. 3, it is difficult to calculate the image quality evaluation values in a state where there is no information concerning structures (a circuit pattern, etc.) in a captured image and concerning the positions of the structures. For example, the image quality evaluation value E1 related to sharpness represents the degree of brightness change at an edge of a circuit pattern, as a structure, or the like. However, in a state where there is no information concerning structures and their positions in a captured image 201, information concerning such an area that does not contribute to evaluation of sharpness and has a large brightness change caused by noise or the like at a flat section is also included in calculation of the image quality evaluation value undesirably. As a result, the precision of the image quality evaluation value lowers.

In view of this, in the first embodiment, at Step S21, the computer system 3 performs area segmentation such that each area in the image 201 corresponds to a structural element of a semiconductor device, and then performs classification as to which segmentation area, that is, which classification segmentation area Rj, corresponds to which structural element. Then, at Step S22, by using the classification segmentation areas Rj and information concerning classification results, the computer system 3 determines, as an evaluation partial area Si, an area suited for calculation for each image quality evaluation value Ei.

FIG. 10 depicts a detailed process example of Step S2. First, the computer system 3 performs processes of Steps S1001 and S1002 corresponding to Step S21 of segmentation/classification, on an evaluation target image 201. At Step S1001, the computer system 3 performs area segmentation of the whole image 201 into respective areas according to structural elements of a semiconductor device seen in the image 201, and tentatively obtains segmentation areas yet to be classified. At Step S1002, on the basis of the segmentation areas, the computer system 3 performs classification by respective structural elements such that each segmentation area in the image 201 corresponds to a structural element of the semiconductor device, and determines classification segmentation areas Rj which are segmentation areas obtained after the classification.

At Steps S1001 and S1002, as inputs, not only the image 201 of the sample 10 but also the design data 206 of a semiconductor pattern, the image capturing conditions 205, and classification information 207 from the user corresponding to the image 201 may be used. The design data 206 includes information concerning the position and shape of a circuit pattern of the wafer 10, which is the sample 10, for example. For example, the image capturing conditions 205 are information concerning conditions for controlling irradiation with the electron beam b1 by the SEM 2 in FIG. 1 or conditions related to detection. For example, the classification information 207 from the user is information for use in segmentation into classification segmentation areas Rj and classification, the information being set by the user operating a GUI screen (e.g., Step S7 in FIG. 6) while looking at the captured image and the like.

At Step S2, specifically, a rule-based segmentation technique such as a Watershed method or a machine learning segmentation technique such as a CNN may be used. In addition, at Step S2, the area segmentation and the area classification may be executed simultaneously using a semantic segmentation technique such as an FCN (Fully Convolutional Network).

By Step S21 (S1001 and S1002 in FIG. 10) of segmentation/classification, a classification result 1010 of the classification segmentation areas Rj is obtained. In the present example, the classification result 1010 includes a defective area 1011, lower layer areas 1012, edge areas 1013, and wiring upper surface areas 1014 as the classification segmentation areas Rj as illustrated in the figure, but this is not the sole example. These areas are areas corresponding to structural elements of the semiconductor device and are associated with the classification segmentation areas Rj. The following is an example of association with classification segmentation areas Ri, identification, and classification in data/information of the classification result 1010: R1=defective area 1011, R2=lower layer areas 1012, R3=edge areas 1013, and R4=wiring upper surface areas 1014.

The defective area 1011 is an area roughly suspected of being defective and is different from a result of defect observation at Step S5 itself. The lower layer areas 1012 are areas on the lower layer side in the image capturing direction and in the semiconductor device structure, and, in other words, are dark areas. The wiring upper surface areas 1014 are areas on the upper surface side in the image capturing direction and in the semiconductor device structure, and are vertical line pattern areas in the present example. The edge areas 1013 are areas forming edges of the wiring upper surface areas 1014.

Thereafter, at Step S1003 corresponding to Step S22, on the basis of the classification result 1010, the computer system 3 extracts evaluation partial areas Si corresponding to image quality evaluation values Ei, thereby determining evaluation partial areas Si (1020). In the illustrated evaluation partial areas 1020, an illustrated white area in each image G1 to GN represents an area that corresponds to the evaluation partial area Si and is used for calculation of an image quality evaluation value Ei, and an illustrated black area in each image G1 to GN represents an area that does not correspond to the evaluation partial area Si and is not used for calculation of an image quality evaluation value Ei. In calculation of image quality evaluation values Ei at the subsequent Step S31, the computer system 3 uses only the white areas, which are the evaluation partial areas Si, in the image 201 and does not use the black areas for the calculation of the image quality evaluation values Ei.

For example, the evaluation partial area S1 for the image quality evaluation value E1 “sharpness” is formed using the extracted classification segmentation area R3=edge areas 1013 (represented by diagonal line patterns). Specifically, the evaluation partial area S1 is formed by enlarging the widths of the edge areas 1013 (R3). In addition, for example, the evaluation partial area S5 for the image quality evaluation value E5 “degree of dark area emphasis” is formed using the extracted classification segmentation area R2=lower layer areas 1012 (represented by diagonal line patterns).

The evaluation partial areas Si output as the result of Step S2 may manually be corrected by the user after being stored on a memory resource. As mentioned later, for example, the computer system 3 displays the evaluation partial areas Si on a GUI screen, and the user looks at and checks the GUI screen, corrects the evaluation partial areas Si as necessary, and confirms and stores the evaluation partial areas Si.

### [Classification Method of Classification Segmentation Areas Rj by Use of Design Data]

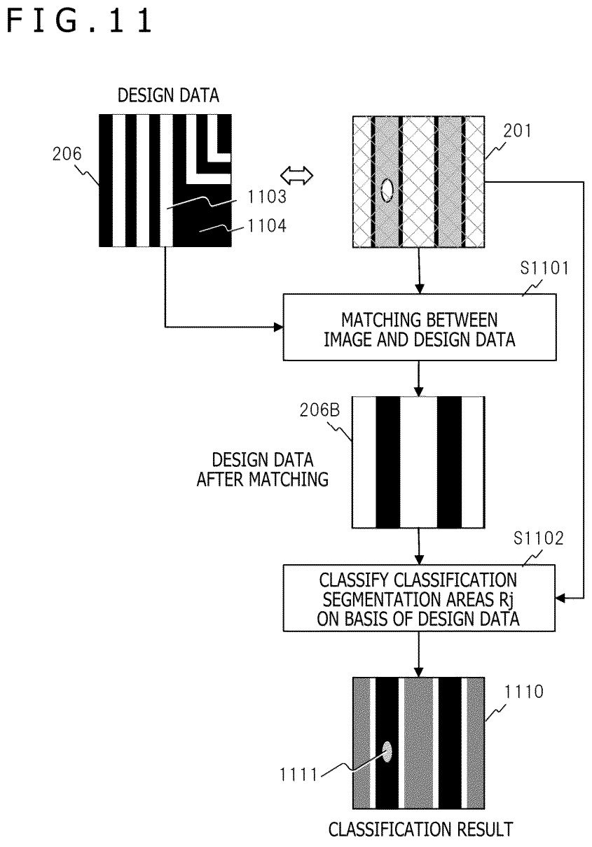

A detailed process example of a classification method of classification segmentation areas Rj at Step S21 of segmentation/classification in FIG. 2 (Step S1001 and S1002 in FIG. 10) by use of the design data 206 of a semiconductor pattern corresponding to an image 201 is explained using FIG. 11.

One of features of the first embodiment (in particular, an implementation example in FIG. 11) is that, at Step S21 of segmentation/classification, classification is performed for each classification segmentation area Rj by use of, as an input, the design data 206 of a semiconductor circuit corresponding to the image 201.

There has been a problem that it is not possible or difficult to classify an evaluation target image into structural elements of a semiconductor. In this regard, in the first embodiment (FIG. 11), the design data 206 of a semiconductor is used as a structural element classification criterion in classification of classification segmentation areas Rj. Thus, it becomes possible to classify classification segmentation areas Rj.

FIG. 11 depicts a process example of classification using the design data 206. First, the computer system 3 receives an input of the design data 206 of a semiconductor corresponding to the evaluation target image 201. The design data 206 in the present example has illustrated white portions 1103 corresponding to an upper surface wiring area, and illustrated black portions 1104 corresponding to a dark area. The design data 206 in the present example includes an area of a structural element corresponding to a circuit pattern in the image 201. The design data 206 includes not only a wiring pattern captured in the image 201 but also other wiring patterns. Accordingly, at Step S1101, the computer system 3 performs matching between the image 201 and the design data 206 by using the image 201 and the design data 206 as inputs, and acquires design data 206B after the matching. The design data 206B after the matching is data that is included in the design data 206 and corresponds to a portion of the wiring pattern captured in the image 201.

Thereafter, at Step S1102, which is a classification step, the computer system 3 classifies classification segmentation areas Rj of the image 201 on the basis of the design data 206B obtained after the matching, and acquires a classification result 1110. Note that a defective area 1111 in the classification result 1110 can be determined by extracting an area where the difference in average brightness from the upper surface wiring area or from the dark area is large.

### [Classification Method of Classification Segmentation Areas Rj by Use of Image Capturing Conditions]

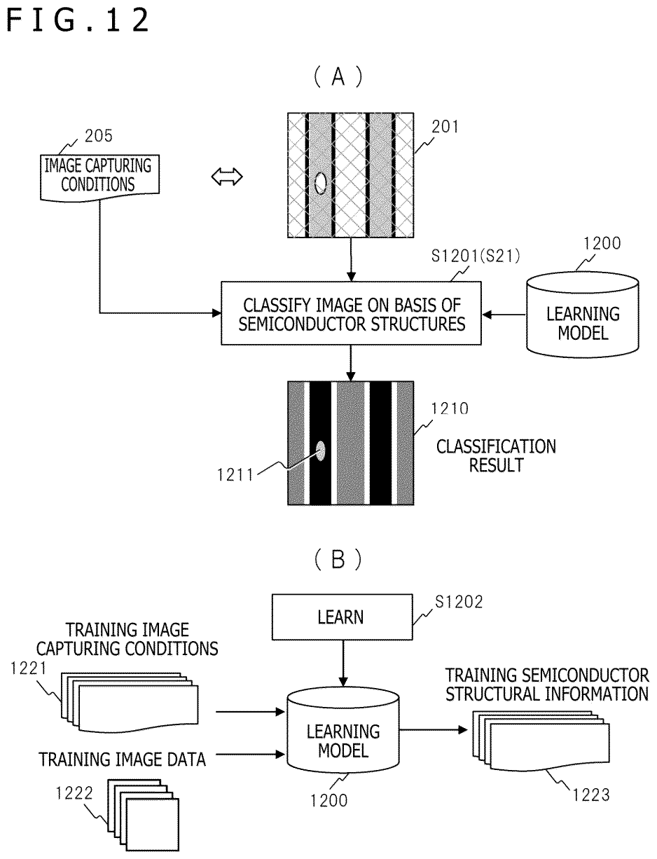

A detailed process example of a classification method of classification segmentation areas Rj at Step S21 of segmentation/classification (Steps S1001 and S1002 in FIG. 10) by use of the image capturing conditions 205 of an evaluation target image 201 is explained using FIG. 12.

One of features of the first embodiment (in particular, an implementation example in FIG. 12) is that, at Step S21 of classification, classification is performed for each classification segmentation area Rj by use of, as an input, the image capturing conditions 205 of the image 201.

There has been a problem that it is not possible or difficult to classify an evaluation target image into structural elements of a semiconductor. In this regard, in the first embodiment, the image capturing conditions 205 of the evaluation target image 201 are used as structural element classification criteria in classification of classification segmentation areas Rj. Thus, it becomes possible to classify classification segmentation areas Rj.

(A) in FIG. 12 depicts a process example of classification using the image capturing conditions 205. At Step S1201 corresponding to Step S21 of segmentation/classification, the computer system 3 classifies classification segmentation areas Rj of the evaluation target image 201 on the basis of semiconductor structures by use of, as inputs, the image 201 and the image capturing conditions 205 used in image capturing of the image 201, and acquires a classification result 1210.

At Step S1201 of classification, for example, after having learned in advance the relation among the acceleration voltage, which is included in the image capturing conditions 205, brightness values of images 201, and the materials of semiconductor structures, the computer system 3 estimates, as an output, the materials of structures from acceleration voltage and brightness values, which are inputs, on the basis of a learning model 1200, and classifies the classification segmentation areas Rj on the basis of an estimation result.

(B) in FIG. 12 depicts an example of a prior learning phase. At Step S1202 of learning, the computer system 3 constructs the learning model 1200 using training image capturing conditions 1221, training image data 1222, and training semiconductor structural information 1223 (including information concerning the materials of semiconductor structures), and performs learning/training of the learning model 1200. For example, by the training, adjustments are made to make parameter values of the learning model 1200 preferable.

Note that, for example, a defective area 1211 in the classification result 1210 can be determined by extraction of an area where a material cannot be estimated.

### [Step of Determining Si by Use of Rj]

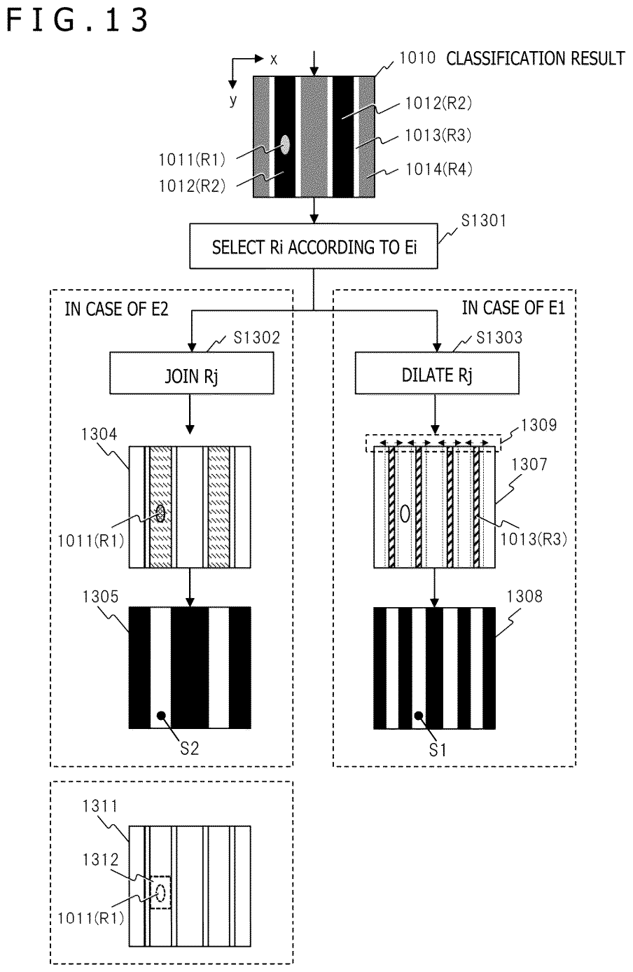

Details of Step S22 (FIG. 2) of determining evaluation partial areas Si by use of classification segmentation areas Rj are explained using FIG. 13. One of features of the first embodiment is that, at Step S2 (S21 and S22) in FIG. 2, in particular in FIG. 13, an evaluation partial area Si for each image quality evaluation value Ei is generated by joining, segmenting, dilating, or eroding classification segmentation areas Rj or a combination of them.

There is a problem that, depending on image quality evaluation values Ei, evaluation partial areas Si, which are areas suited for calculation of the image quality evaluation values Ei, and classification segmentation areas Rj segmented/classified according to semiconductor structures do not necessarily match in some cases. In this case, even if an image quality evaluation value Ei is calculated simply for each classification segmentation area Rj, a desired image quality item cannot be evaluated, in other words, it is difficult to enhance the precision of image quality evaluation. For example, the image quality item “defect visibility” denoted as the image quality evaluation value E2 in FIG. 3 represents the ease of distinguishing a defective area from a surrounding area as in (2a) and (2b) in FIG. 4. Accordingly, for the image quality item “defect visibility,” the image quality evaluation value E2 is preferably calculated regarding an area including not only the defective area but also the surrounding area.

In this regard, in the first embodiment, an evaluation partial area Si, which is an area suited for calculation of an image quality evaluation value Ei, is generated by applying one process selected from processes of joining, segmenting, dilating, and eroding classification segmentation areas Rj, or by applying a combination of a plurality of processes selected from them. Consequently, it becomes possible to calculate an image quality evaluation value Ei even for an area including a plurality of classification segmentation areas Rj or for a partial area in a classification segmentation area Rj.

FIG. 13 depicts a process example of generating an evaluation partial area Si by a process of joining, segmenting, dilating, or eroding classification segmentation areas Rj or by another process. It is assumed that the classification result 1010 used as an input is the same as that in FIG. 10. First, the setting of an evaluation partial area Si in a case where the image quality evaluation value Ei is the image quality evaluation value E2 “defect visibility” is taken as an example. In a case where the image quality evaluation value E2 “defect visibility” is calculated, the contrast between a defective area and a surrounding area influences the evaluation value. Accordingly, not only the defective area but also the surrounding area which is an area adjacent to the defective area needs to be included in the evaluation partial area Si.

Accordingly, at Step S1301, the computer system 3 selects classification segmentation areas Rj according to the image quality evaluation value Ei (E2) in the classification result 1010. As the classification segmentation areas Rj, the computer system 3 selects a defective area 1011 (R1) and a dark area 1012 (R2) which is an area adjacent to the defective area 1011 (R1). FIG. 13 depicts the classification segmentation areas Rj selected here, also as hatching pattern areas in an image 1304. Then, at Step S1302, the computer system 3 generates an evaluation partial area S2 for the image quality evaluation value E2 “defect visibility” by joining the selected defective area 1011 (R1) and area 1012 (R2). A white portion in an image 1305 as a generation result is the evaluation partial area S2.

An image 1311 depicts another example of calculation of the evaluation partial area S2 for the image quality evaluation value E2. This example depicts a case where, when a surrounding area of the defective area 1011 (R1) is obtained, not the entire adjacent dark area 1012 (R2) but only a partial range that is in the adjacent dark area 1012 (R2) and is close to the defective area 1011 (R1), or only a range 1312 represented by a rectangle in the present example, is used.

As another example, determination of the evaluation partial area S1 in a case where the image quality evaluation value Ei is “sharpness” of the image quality evaluation value E1 in FIG. 3 is as follows. In a case where the computer system 3 calculates the image quality evaluation value E1 of “sharpness,” the computer system 3 calculates the degree of brightness change at the boundary (i.e., the edge, etc.) between areas with different semiconductor structures or materials. The calculation of the degree of brightness change requires acquisition of a change amount by comparison of the brightness of an edge area with the brightness of its surrounding area. Hence, it is necessary to include not only the edge area but also a surrounding area of the edge area in the evaluation partial area S1 for the image quality evaluation value E1.

Accordingly, the computer system 3 selects classification segmentation areas Rj according to the image quality evaluation value E1 in the classification result 1010. The computer system 3 first selects the areas 1013 (R3), which are edge areas, as classification segmentation areas Rj. The areas selected here are depicted also as hatching pattern areas in an image 1307. At Step S1303, the computer system 3 generates the evaluation partial area S1 of the image quality evaluation value E1 related to “sharpness” by dilating the areas 1013 (R3), which are edge areas. In the present example, as depicted as dilating directions 1309 in the image 1307, the computer system 3 dilates the respective areas 1013 (R3), which are edges of vertical line patterns extending in the y-axis direction, in both of the left and right directions in the x direction which are directions orthogonal to the vertical line patterns and are represented by arrows. White portions in an image 1308 as a generation result are the evaluation partial area S1.

Evaluation partial areas Si for other image quality evaluation values Ei also can be generated by processes using classification segmentation areas Rj on the basis of the definition of a process for each image quality evaluation value Ei, as with the examples described above. In addition, depending on image quality evaluation values Ei, evaluation partial areas Si can be generated not only by joining or dilating classification segmentation areas Rj as in the examples described above, but by segmenting or eroding classification segmentation areas Rj or by a combination of these. As an example of segmentation of classification segmentation areas Rj, each wiring upper surface area 1014 (R4) may be segmented into a plurality of areas according to the relation regarding distance/nearness to an edge area 1013 (R3) or the like. As an example of erosion of a classification segmentation area Rj, each wiring upper surface area 1104 (R4) may be eroded such that areas close to edge areas 1103 (R3) are excluded.

The method of generating an evaluation partial area Si from classification segmentation areas Rj for each image quality evaluation value Ei mentioned above may be set by the user as a rule-based generation method or may be set by the user as a generation method using machine learning at Step S62 in FIG. 6.

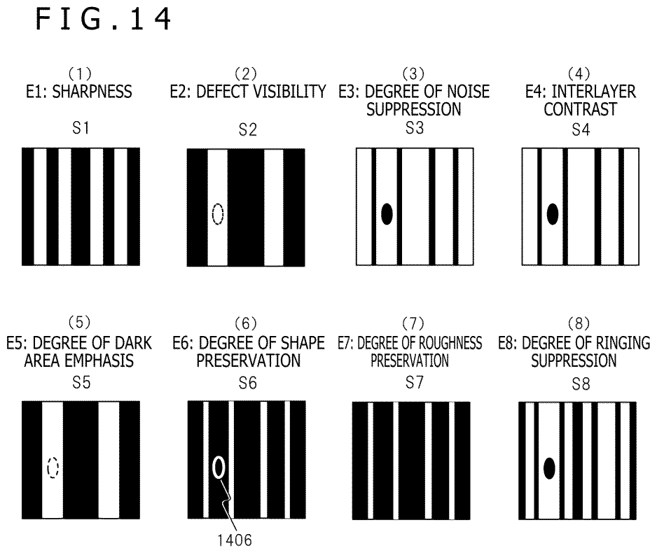

FIG. 14 depicts examples of generation results of evaluation partial areas Si (S1 to S8) for the respective image quality evaluation values Ei (E1 to E8) including examples of other image quality evaluation values Ei. White portions in each image represent an evaluation partial area Si. For example, in the case of the image quality evaluation value E3 “degree of noise suppression,” the computer system 3 generates the evaluation partial area S3 from the wiring upper surface areas 1014 (R4) and the dark areas 1012 (R2) mentioned before. In addition, in the case of the image quality evaluation value E4 “interlayer contrast,” the computer system 3 generates the evaluation partial area S4 from the wiring upper surface areas 1014 (R4) and the dark areas 1012 (R2) mentioned before. In addition, in the case of the image quality evaluation value E5 “degree of dark area emphasis,” the computer system 3 generates the evaluation partial area S5 from the wiring upper surface areas 1014 (R4) and the defective area 1011 (R1) mentioned before.

In addition, for example, in the case of the image quality evaluation value E6 “degree of shape preservation,” the computer system 3 generates the evaluation partial area S6 such that it is made possible to evaluate whether or not not only the shape of a surrounding area of an edge of a pattern but also the shape of a defective area is preserved. An area 1406 is an area with a width which is enlarged to some extent such that the area 1406 includes the line of the shape (e.g., an ellipse) of the defective area 1011 (R1). In addition, in the case of the image quality evaluation value E7 “degree of roughness preservation,” the computer system 3 generates the evaluation partial area S7 from the edge areas 1013 (R3) mentioned before. In addition, in the case of the image quality evaluation value E8 “degree of ringing suppression,” the computer system 3 generates, as the evaluation partial area S8, areas that are around edges but exclude edge areas (e.g., areas within a predetermined distance from the edge areas).

### [Classification Criteria of Classification Segmentation Areas Rj]

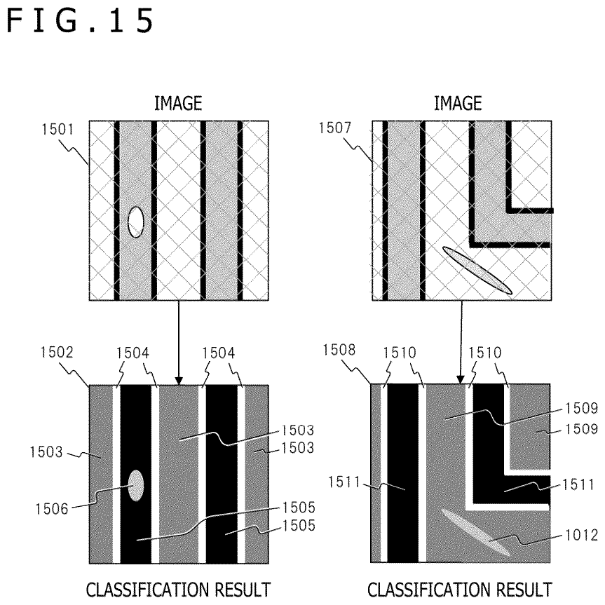

Classification criteria of classification segmentation areas Rj related to Step S21 in FIG. 2 are explained using FIG. 15. One of features of the first embodiment is that classification segmentation areas Rj include, as a type or classification, at least one of a wiring upper surface area, an edge area, a dark area, and a defective area. Such classification segmentation areas Rj correspond to the defective area 1011, the dark areas 1012, the edge areas 1013, and the wiring upper surface areas 1014 in the example in FIG. 10.

There is a problem that it is difficult in some cases to specify classification criteria of classification segmentation areas Rj for determining evaluation partial areas Si since the appearance of images differ significantly. In this regard, in the first embodiment, paying attention to semiconductor structure information, classification segmentation areas Rj are classified such that at least one of a wiring upper surface area, an edge area, a dark area, and a defective area is included. For example, as mentioned before, the defective area 1011 is classified as the first classification segmentation area R1, the dark areas 1012 are classified as the second classification segmentation areas R2, the edge areas 1013 are classified as the third classification segmentation areas R3, and the wiring upper surface areas 1014 are classified as the fourth classification segmentation areas R4.

FIG. 15 is a diagram for explaining the classification criteria described above. A wiring upper surface area is an area that is occupied by a wiring pattern at the highest position in the direction (Z-direction) perpendicular to the wafer surface in a top view image of the wafer surface captured from above. A dark area is an area that is occupied by a wiring pattern, a background portion, or the like at the lowest position in the direction (Z-direction) perpendicular to the wafer surface in the top view image of the wafer surface captured from above. An edge area is a boundary area between the wiring upper surface area and the dark area. A defective area is a rough area suspected of being defective such as an unintended pattern or foreign matters.

In the example in FIG. 15, an image 1501 depicted on the left side is an image similar to the image 201 mentioned before. A result of classification of the image 1501 into a plurality of classification segmentation areas Rj is depicted as a classification result 1502. In the classification result 1502, areas in the image 1501 are classified into four types of classification segmentation areas Rj (e.g., R1 to R4), which are wiring upper surface areas 1503, edge areas 1504, dark areas 1505, and a defective area 1506. Note that, as in the illustrated example, a plurality of classification segmentation areas Rj of one type may be present at separate positions.

In another example, an image 1507 depicted on the right side is an image captured of a pattern that has appearance different from that of the image 1501 but has the same structure. A result of classification of the image 1507 is depicted as a classification result 1508. In the classification result 1508 as well, as with the classification result 1502, areas in the image 1507 are classified into four types of classification segmentation areas Rj, which are wiring upper surface areas 1509, edge areas 1510, dark areas 1511, and a defective area 1512.

As in the example described above, standardized classification becomes possible by paying attention to semiconductor structural information concerning images in which the same structure is captured but which have different appearance. The semiconductor structural information here may be structural information that can be found by image analysis of the captured image 201 or may be structural information that can be found from the design data 206.

While an image is classified into four types of areas, which are wiring upper surface areas, edge areas, dark areas, and a defective area in the example of the first embodiment, this is not the sole example. For example, in the case of a structure including three or more layers of wire, other areas such as a wiring intermediate layer area may be added to classification results. In addition, edge areas may be set not only as the boundaries between wiring upper surface areas and dark areas, but also as the boundaries between areas of respective layers such as the boundaries between wiring upper surface areas and wiring intermediate layer areas or the boundaries between wiring intermediate layer areas and dark areas.

### [Method of Determining Internal Parameters Related to Calculation of Ei]

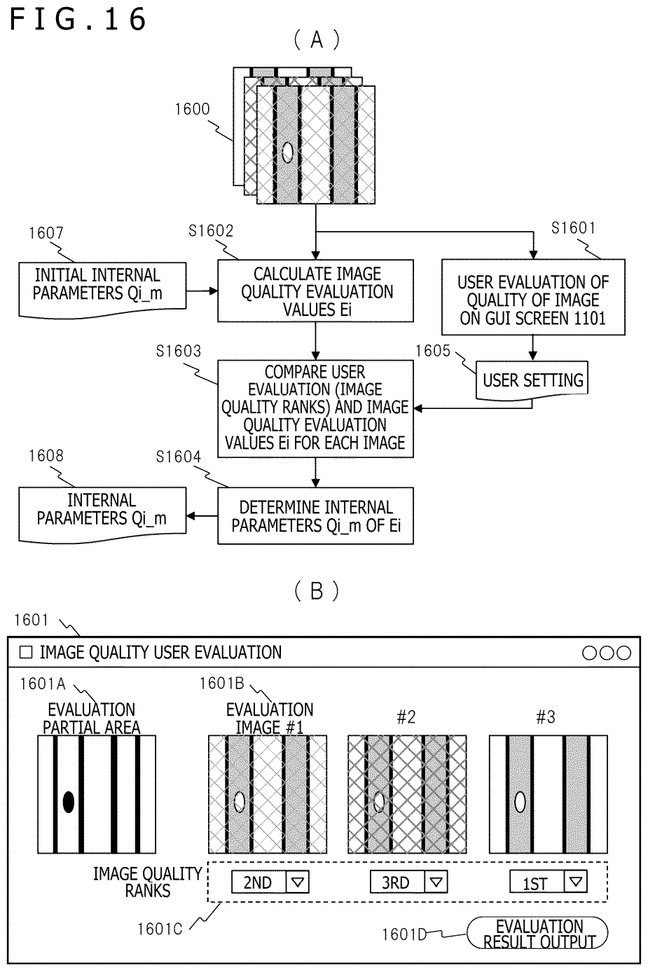

A method of determining, at Step S63 in FIG. 6, internal parameters Qi_m related to calculation of image quality evaluation values Ei at Step S31 is explained using FIG. 16.

In the first embodiment, there is an interface to which results of evaluation by the user related to image quality are input, and there is Step S63 of determining a calculation method of image quality evaluation values Ei by use of the user evaluation results. One of features of Step S63 is that the computer system 3 calculates image quality evaluation values Ei by using the internal parameters Qi_m (m=1 to Nm) and determines the internal parameters Qi_m such that the image quality evaluation values Ei match the user evaluation results or the image quality evaluation values Ei approach the user evaluation results as much as possible. The internal parameters Qi_m are parameters to form the image quality evaluation values Ei, in other words, parameters to be used in processes in a method of calculating the image quality evaluation values Ei. m=1 to Nm, and Nm is the number of internal parameters.

There is a problem that, in evaluation of image quality, different users have different criteria in determining whether the image quality is good or bad, and calculation results of image quality evaluation values Ei designed in advance and results of evaluation by the users do not match in some cases. In this regard, in the first embodiment, attention is paid to the fact that image quality evaluation values Ei change depending on the internal parameters Qi_m to be used when the image quality evaluation values Ei are calculated. In the first embodiment, the internal parameters Qi_m are determined such that calculation results of image quality evaluation values Ei and user evaluation results match. Thus, the problem that calculation results of image quality evaluation values Ei and user evaluation results do not match is solved.

FIG. 16 is a diagram for explaining determination of internal parameters Q described above. (A) depicts a process example, and (B) depicts a GUI screen example corresponding to (A). In (A), the computer system 3 receives an input of an evaluation target image group 1600. The image group 1600 includes a plurality of images that are obtained by image capturing at the same position of a wafer and are different in image quality. At Step S1601, the computer system 3 provides the user with a GUI 1601, and the user inputs results of evaluation of image quality of the images on the GUI 1601.

In the first embodiment, as depicted in (B), there is a GUI screen 1601 as the GUI 1601 on which results of evaluation by the user related to image quality of the images are input. In the computer system 3, the GUI screen 1601 displays an evaluation partial area 1601A for calculation of a target image quality evaluation value Ei, and a plurality of images (user evaluation images) 1601B being different in image quality. The evaluation partial area 1601A corresponds to an evaluation partial area Si determined as in Step S2 mentioned before with an image in the image group 1600 as a target. In the present example, as represented by white portions, wiring upper surface areas and dark areas are areas for calculation of the image quality evaluation value Ei. As the user evaluation images 1601B, for example, three images (#1, #2, and #3) that correspond to the image group 1600 and are different in image quality are displayed.

The user evaluation images 1601B are provided with an image quality evaluation interface 1601C. The user visually checks the user evaluation images 1601B on the GUI screen 1601, evaluates subjectively, and inputs ranks of the quality of respective images on the image quality evaluation interface 1601C. In other words, the user judges which one of the user evaluation images 1601B has relatively higher or lower image quality, and so on, and inputs ranks. For example, ranks can be selected from list boxes in the image quality evaluation interface 1601C. This is not the sole example, and the image quality evaluation interface 1601C may be an interface on which the user arranges the images in order of image quality by dragging them, or the like. After ending input of image quality ranks, the user presses an evaluation result output button 1601D. Thus, the computer system 3 stores/outputs, as user settings 1605 (the user setting information 202 in FIG. 2), user evaluation results including the image quality ranks set by the user. Step S1601 of image quality evaluation by the user on the GUI screen 1601 corresponds to Step S7 of user setting in FIG. 2.

After the user settings 1605 are stored/output, at Step S1602, the computer system 3 calculates the image quality evaluation value Ei of each image in the user evaluation images 1601B (the corresponding image group 1600) displayed to the user on the GUI screen 1601. At this time, the computer system 3 calculates the target image quality evaluation value Ei of each image by using initial internal parameters 1607 prepared in advance.

Next, at Step S1603, the computer system 3 compares the image quality evaluation values Ei of the respective images obtained at Step S1602 with the image quality ranks, which are user evaluation results obtained in the user settings 1605. In this comparison, the computer system 3 checks whether or not the magnitude relation among the image quality evaluation values Ei of the respective images and the image quality ranks set by the user match. In a case where they do not match, it is judged that internal parameter adjustments are necessary.

Thereafter, at Step S1604, the computer system 3 determines the internal parameters Qi_m of the image quality evaluation values Ei by using obtained comparison results. At this time, the computer system 3 determines the values of the internal parameters Qi_m such that the magnitude relation among the image quality evaluation values Ei of the user evaluation images 1601B displayed to the user and the image quality ranks set by the user match, and such that significant differences are generated among the image quality evaluation values Ei of the respective images.

Examples of internal parameters Qi_m of image quality evaluation values Ei include the following. In a case where the image quality evaluation values Ei are calculated using a rule-based process, when the sharpness (image quality evaluation value E1) of edges in an image is calculated on the basis of the brightness gradient, for example, examples of internal parameters Qi_m include the filter size of a Sobel filter and the like. In addition, in a case where the image quality evaluation values Ei are calculated using a machine learning model, examples include such model parameters as weights (i.e., coupling coefficients) between nodes of a network or biases, and the like.

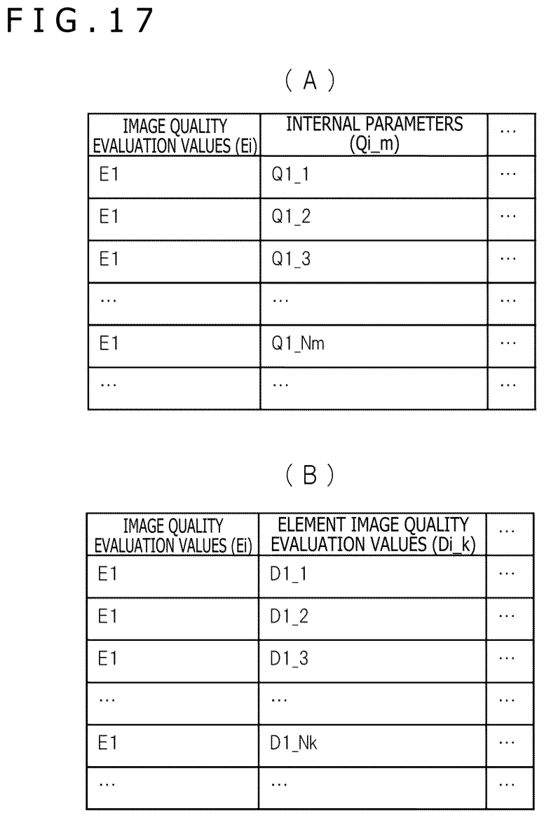

(A) in FIG. 17 depicts a configuration example of data of internal parameters Qi_m of image quality evaluation values Ei. For example, such data/information of internal parameters Qi is managed to be included in the image quality evaluation value information 203 (FIG. 3) mentioned before. The table in (A) in FIG. 17 has a column of image quality evaluation values Ei and a column of internal parameters Qi_m. For example, the image quality evaluation value E1 has internal parameters Q1_1 to Q1_Nm as a plurality of internal parameters Qi_m. Each internal parameter Qi has a set parameter value. In addition, whether or not to use (i.e., ON/OFF) and so on may be set for each internal parameter Qi.

### [Element Image Quality Evaluation Values Related to Calculation of Ei]

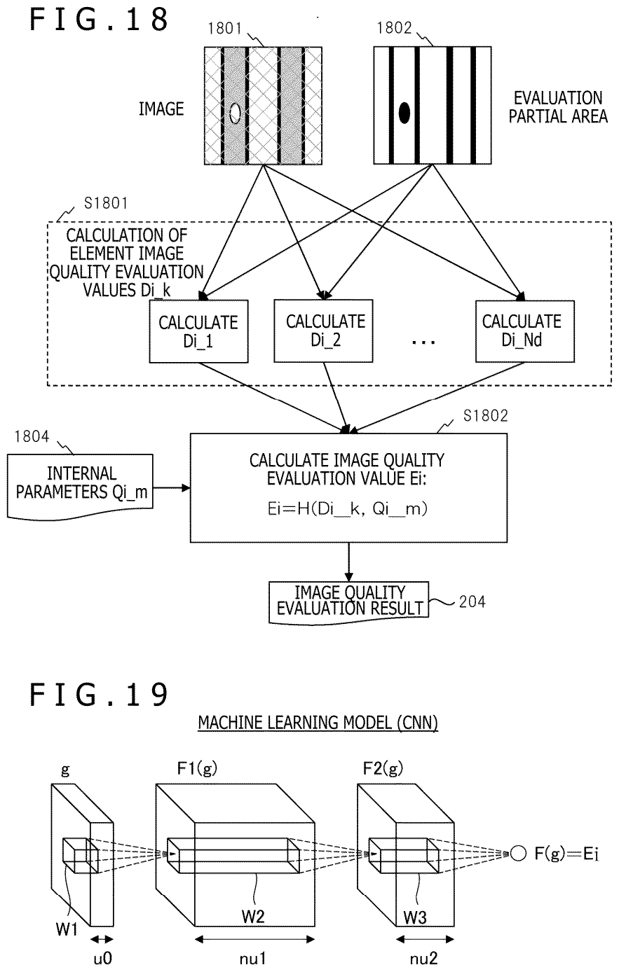

“Element image quality evaluation values” related to calculation of image quality evaluation values Ei are explained using FIG. 18. One of features of the first embodiment is that image quality evaluation values Ei may be expressed by combinations of element image quality evaluation values Di_k (k=1 to Nd). Nd is the number of element image quality evaluation values. In addition, one of features of the first embodiment is that internal parameters Qi_m of image quality evaluation values Ei may be parameters designating combination methods of element image quality evaluation values Di_k.

There has been a problem that, since it is difficult to change image feature elements to be taken into consideration in calculation of image quality evaluation values Ei, it is difficult to cope with changes in variation of semiconductor structures as evaluation targets. In this regard, in the first embodiment, image quality evaluation values Ei are expressed by combinations of element image quality evaluation values Di_k. Thus, it becomes possible to change image quality evaluation values Ei according to variations of semiconductor structures and changes thereof, and preferable image quality quantification becomes possible.

FIG. 18 is an explanatory diagram related to element image quality evaluation values Di. A process example in FIG. 18 can be applied to Step S3 (FIG. 2). In addition, this process example can be applied to each image quality evaluation value Ei. It is assumed that an evaluation target image 1801 and an evaluation partial area 1802 that corresponds to the image 1801 and is for calculation of an image quality evaluation value Ei are given. In this case, at Step S1801, the computer system 3 calculates a plurality (Nd) of element image quality evaluation values Di_k related to the target image quality evaluation value Ei, using the image 1801 and the evaluation partial area 1802 as inputs. Thereafter, at Step S1802, using the Nd element image quality evaluation values Di_k and internal parameters (Qi_m) 1804 related to the target image quality evaluation value Ei as inputs, the computer system 3 calculates the image quality evaluation value Ei formed by combining the Nd element image quality evaluation values Di_k. This calculation is expressed as Ei=H (Di_k, Qi_m). H is a function of Di. The internal parameters (Qi_m) 1804 referred to at Step S1802 are information designating a combination method of the element image quality evaluation values Di_k. As a result of Step S1802, the image quality evaluation result 204 including the image quality evaluation value Ei is obtained.

(B) in FIG. 17 depicts a configuration example of data concerning element image quality evaluation values Di_k of image quality evaluation values Ei. For example, such data/information concerning element image quality evaluation values Di_k is managed to be included in the image quality evaluation value information 203 (FIG. 3) mentioned before. The table in (B) in FIG. 17 has a column of image quality evaluation values Ei and a column of element image quality evaluation values Di_k. For example, the image quality evaluation value E1 has element image quality evaluation values D1_1 to D1_Nk as a plurality of element image quality evaluation values Di_k. A parameter value is set for each element image quality evaluation value Di_k. In addition, whether or not to use (i.e., ON/OFF) and so on may be set for each element image quality evaluation value Di_k.

Explained as follows is a case where it is assumed that one of internal parameters Qi_m of an image quality evaluation value Ei is a parameter designating a combination method of element image quality evaluation values Di_k. For example, it is assumed that one of internal parameters Q1_m of the image quality evaluation value E1 is a parameter designating a combination method of element image quality evaluation values D1_k. An example of a combination method is a method of using all the element image quality evaluation values D1_k (k=1 to Nk). In this case, the one internal parameter Q1_m designating the combination method is information representing that all the element image quality evaluation values D1_k (k=1 to Nk) are used. For example, in a case where whether or not to use each element image quality evaluation value D1_k is represented by ON (1)/OFF (0), the internal parameter Q1_m takes values such as {1, 1, . . . 1}.

This is not the sole example, and an internal parameter designating a combination method may be information designating the function used at Step S1802 in FIG. 18. In addition, setting information may be provided separately from internal parameters, and, for example at Step S63 in FIG. 6, a method of calculation of an image quality evaluation value Ei including a combination method of the element image quality evaluation values D1_k or a function described above may be set.

Following is a specific example related to the element image quality evaluation values Di described above. Explained is a case where the image quality evaluation value E3 “degree of noise suppression” in FIG. 3 is calculated as an image quality evaluation value Ei, and where element image quality evaluation values D3_k (e.g., D3_1 and D3_2) forming the image quality evaluation value E3 are obtained. First, in order to calculate a noise-caused brightness change amount in the target image 1801, treating each pixel of the image 1801 as a target pixel in the evaluation partial area 1802, the computer system 3 calculates a local average value of the brightness of the target pixel and surrounding pixels, and calculates the difference between the brightness of the target pixel and the local average value. By calculating the differences regarding all the pixels by a procedure like the one described above, the computer system 3 obtains a noise-caused brightness change as an element image quality evaluation value D3_1, which is a first element.

Meanwhile, the impression that noise generated in the image 1801 gives to the user changes not only due to a noise-caused brightness change but also due to the image contrast. Accordingly, the computer system 3 calculates the contrast of the image 1801 as an element image quality evaluation value D3_2, which is a second element.

For example, the image quality evaluation value E3 “degree of noise suppression” is formed by combining two elements, which are the element image quality evaluation value D3_1 (“noise-caused brightness change”) and the element image quality evaluation value D3_2 (“image contrast”) described above. This combination method can be designated by one of the internal parameters Qi_m. Thus, the computer system 3 can calculate the preferable image quality evaluation value E3 “degree of noise suppression” taking into consideration both a noise-caused brightness change and the image contrast. While a “noise-caused brightness change” (the difference described above) and the image contrast are used in order to calculate “degree of noise suppression” in the example described above, this is not the sole example. Image quality evaluation values Ei can be calculated using other element image quality evaluation values Di.

### [Calculation of Ei by Use of Machine Learning]

With reference to FIG. 19, a method of calculating image quality evaluation values Ei by use of machine learning is explained. One of features of the first embodiment is that, at Step S3 of calculating image quality evaluation values in FIG. 2, image quality evaluation values Ei may be calculated using a machine learning model.

There has been a problem that, regarding image quality items determined subjectively by humans such as image naturalness, it is difficult to determine image features related to calculation of evaluation values in advance, and quantitative evaluation is difficult. In this regard, in the first embodiment, in a case where machine learning is used at Step S3, image quality evaluation values Ei are calculated using a machine learning model for which learning has been performed using human subjectivity or the like as teaching data. Thus, it becomes possible to calculate evaluation values without determining image features in advance.

FIG. 19 depicts an example of a machine learning model applied to Step S3, particularly Step S31, in FIG. 2. As an implementation method of the machine learning, for example, known deep learning can be applied. In a specific example, a convolutional neural network (CNN) can be applied as the model. The example in FIG. 19 depicts a machine learning model using a CNN having a triple-layer structure. In this model, g represents an image as an input, and F(g) is an output of a result of estimation by the model. In addition, F1(g) and F2(g) represent intermediate pieces of data between the input and the estimation result. The intermediate pieces of data F1(g) and F2(g) and the estimation result F(g) are calculated in accordance with the following Formula 1 to Formula 3.

$$F 1 ( g ) = max ( 0 , W 1 * g + B 1 ) \qquad Formula 1$$

$$F 2 ( g ) = max ( 0 , W 2 * F 1 ( g ) + B 2 ) \qquad Formula 2$$

$$F ( g ) = average ( W 3 * F 2 ( g ) + B 3 ) \qquad Formula 3$$

Here, * represents a convolutional arithmetic operation, W1 represents n1 filters with the size of u0×f1×f1, u0 represents the number of channels of an input image, and f1 represents the size of a spatial filter. By convolving the filters with the size of u0×f1×f1 with the input image g nu1 times, a nu1-dimensional feature map is obtained. B1 is an n1-dimensional vector and is a bias component corresponding to the n1 filters. Similarly, W2 represents nu2 filters with the size of nu1×f2×f2, B2 represents an n2-dimensional vector, W3 represents one filter with the size of nu2×f3×f3, and B3 represents one-dimensional vector. u0 is a value determined by the number of channels of an evaluation target image. In addition, f1, f2, nu1, and nu2 are values determined by the user before a learning sequence. For example, f1=9, f2=5, nu1=128, and nu2=64.

In the example in the first embodiment, the estimation result F (g) obtained in accordance with Formula 3 is used as an image quality evaluation value Ei. Note that, for F1, F2, and F, an evaluation partial area Si may be used as a mask. In addition, the configuration example using a CNN described above is not the sole example, and other configurations may be used. For example, the number of layers may be changed, a network with four layers or more or the like may be used, or a configuration having a skip connection may be adopted. In addition, while an example in which an average value is used for calculation of F(g) in Formula 3 is depicted, a maximum value or a minimum value may be calculated.

### [Calculation of Comprehensive Evaluation Value C (Step S32)]

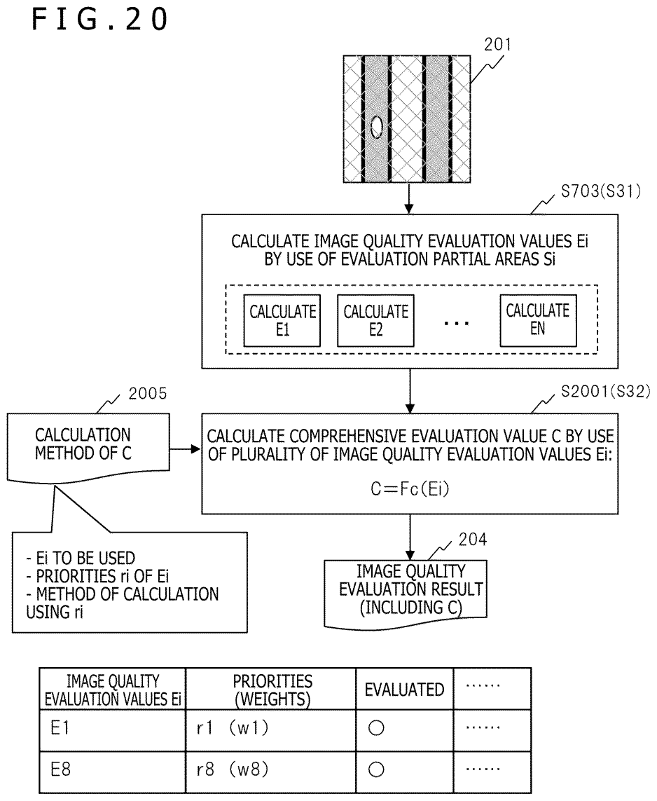

A method of calculating the comprehensive evaluation value C from a plurality of image quality evaluation values Ei at Step S32 in FIG. 2 is explained using FIG. 20. One of features of the first embodiment is that, at Step S32, the comprehensive evaluation value C formed using a combination of image quality evaluation values Ei is calculated.

FIG. 20 is an explanatory diagram related to calculation of the comprehensive evaluation value C. As a result of the process in FIG. 7 mentioned before (particularly, Step S703), the computer system 3 obtains information concerning a plurality of image quality evaluation values Ei for the target image 201. The plurality of image quality evaluation values Ei are a plurality of image quality evaluation values Ei necessary for calculating the comprehensive evaluation value C. Which image quality evaluation values Ei are used for calculating the comprehensive evaluation value C is set as part of the calculation method at Step S64 in FIG. 6.

Next, at Step S2001, the computer system 3 calculates the comprehensive evaluation value C formed using a combination of the plurality of image quality evaluation values Ei described above in accordance with a calculation method 2005 of the comprehensive evaluation value C. The calculation method 2005 of the comprehensive evaluation value C is a setting value of Step S64 in FIG. 6, and, for example, is information specifying which image quality evaluation values Ei in a plurality of image quality evaluation values Ei (i=1 to N) are used, a combination method of the plurality of image quality evaluation values Ei used, and the like. For example, the comprehensive evaluation value C can be expressed as a function of the image quality evaluation values Ei. The calculated comprehensive evaluation value C is stored to be included in the image quality evaluation result 204 along with the related image quality evaluation values Ei.

For example, the comprehensive evaluation value C is calculated using the following Formula 4. Fc described below is a function having image quality evaluation values Ei as an argument. In this case, the calculation method 2005 of the comprehensive evaluation value C is a parameter related to the function Fc.

$$C = Fc ( Ei ) \qquad Formula 4$$

A specific example of calculation of the comprehensive evaluation value C is as follows. For example, typically, an observation image is desired to have high sharpness. However, there is a fear that ringing is amplified in a case where image capturing or an image quality enhancement process is performed in such a manner as to enhance sharpness. That is, there is a trade-off between sharpness and ringing. The sharpness described above relates to the image quality evaluation value E1 “sharpness” in FIG. 3, and the ringing described above relates to the image quality evaluation value E8 “degree of ringing suppression” in FIG. 3. Accordingly, it is difficult in some cases to comprehensively judge whether image quality is good or bad simply by looking at the individual image quality evaluation values Ei.

In view of this, in the first embodiment, for example, the comprehensive evaluation value C formed by combining the image quality evaluation value E1 of sharpness and the image quality evaluation value E8 of the degree of ringing suppression is calculated. This comprehensive evaluation value C makes it possible to comprehensively observe/judge image quality. In addition, for example, by making the method of combining the image quality evaluation value E1 and the image quality evaluation value E8 variable using a parameter, it also becomes possible to set a priority as to on which image quality item emphasis is placed. Thus, it becomes possible to calculate the comprehensive evaluation value C according to the preference of the user.

### [Calculation of Comprehensive Evaluation Value C: Priorities]

One of features of the first embodiment is that the comprehensive evaluation value C may be calculated using priorities given to/set for image quality evaluation values Ei.

There is a problem that there are a case where it is desired to place emphasis on an image quality evaluation value Ei of a particular image quality item in a plurality of image quality evaluation values Ei or other similar cases, and that comprehensive evaluation coping with such cases is difficult. In this regard, in the first embodiment, a priority is given to/set for each image quality evaluation value Ei according to the image quality items on which the user places emphasis, and the comprehensive evaluation value C is calculated using a combination of the image quality evaluation values Ei.

FIG. 20 depicts calculation of the comprehensive evaluation value C using priorities, as well. In the calculation method 2005 of the comprehensive evaluation value C that is depicted in FIG. 20 and can be set at Step S64 in FIG. 6, not only a combination method as to which image quality evaluation values Ei are to be used for calculation of the comprehensive evaluation value C, and so on, but also priorities of the image quality evaluation values Ei to be used, a method of calculation of the comprehensive evaluation value C using the priorities, and the like can be set. It is assumed here that the priorities for the respective image quality evaluation values Ei are ri (i=1 to N).

It is assumed as an example that the comprehensive evaluation value C is defined using E1 to E8 in combination. C=Fc (E1, E8). Priorities ri (r1, r8) are set for the respective image quality evaluation values Ei (E1, E8) to be used. For example, weighting coefficients according to the priorities ri are provided for the respective image quality evaluation values Ei to be used. For example, a weight w1 corresponding to the priority r1, a weight w8 corresponding to the priority r8, and the like are provided. It is assumed that a calculation formula of the comprehensive evaluation value C is the function Fc defined using the weights (i.e., coefficients) according to the priorities ri. For example, C=Fc(E1, E8)=E1×w1+E8×w8. Note that, in the definition in the present example, the greater the value of Ei is, the more highly evaluated Ei is; the higher the priority ri is, the greater the value of the weight wi is; and the greater the value of the comprehensive evaluation value C is, the more highly evaluated comprehensively the comprehensive evaluation value C is. In addition, while weighted addition is performed in the present example, this is not the sole example. A definition using four arithmetic operations or the like is possible. Similarly, the comprehensive evaluation value C can be defined according to arithmetic operations using a plurality of image quality evaluation values Ei and priorities ri.

For example, in a case where the user wants to perform evaluation placing emphasis on the image quality evaluation value E1 “sharpness,” it is sufficient if she/he sets the value of the priority r1 (the corresponding weight w1) to a greater value. In addition, for example, in a case where the user wants to perform evaluation placing emphasis on the image quality evaluation value E8 “degree of ringing suppression,” it is sufficient if she/he sets the value of the priority r8 (the corresponding weight w8) to a greater value. User setting that includes setting of the priorities ri described above and is related to the calculation method 2005 of the comprehensive evaluation value C can also be performed on a GUI screen. In addition, in a case where there are a plurality of calculation methods of the comprehensive evaluation value C depending on the image quality items on which emphasis is to be placed, as in the example described above, it is possible to allow the user to select a calculation method from the plurality of calculation methods at the time of evaluation and apply the selected calculation method, by defining and setting the plurality of calculation methods in advance. In addition, items of priorities ri may be provided in the image quality evaluation value information 203 in FIG. 3.

### [Use Example of Image Quality Evaluation Values Ei]

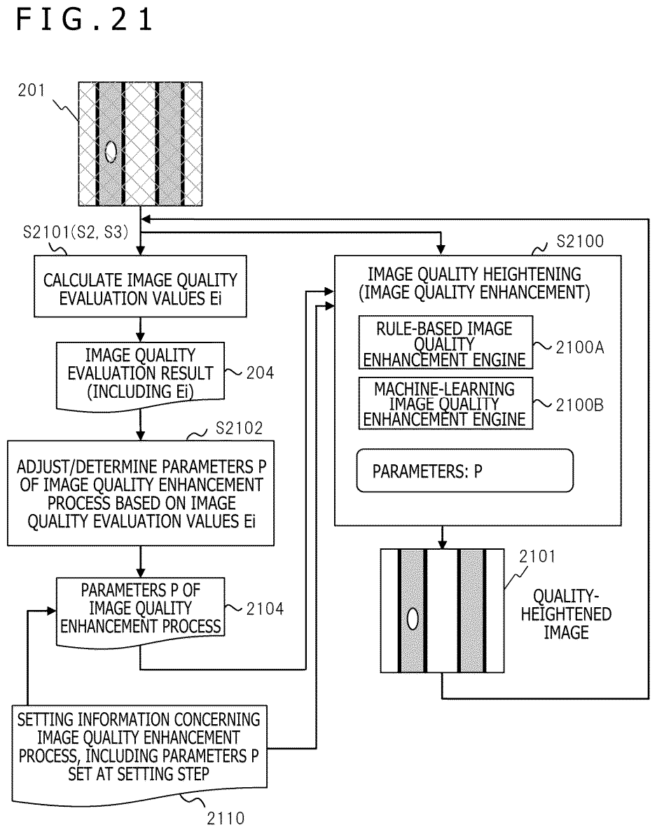

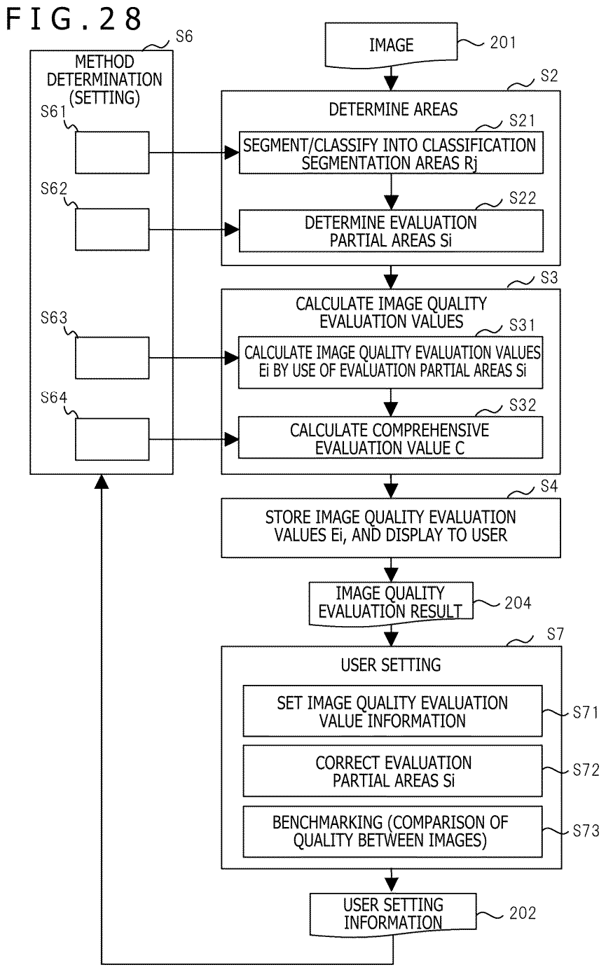

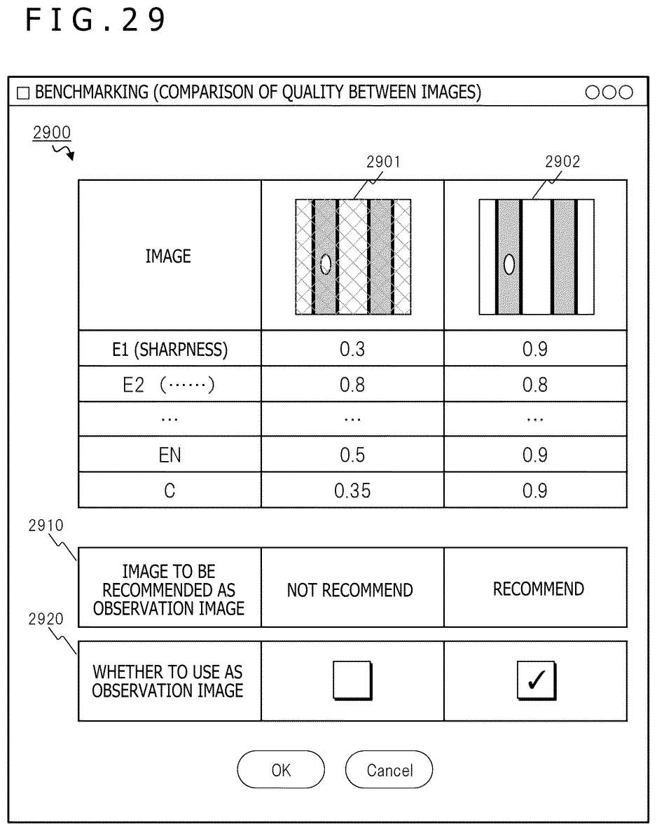

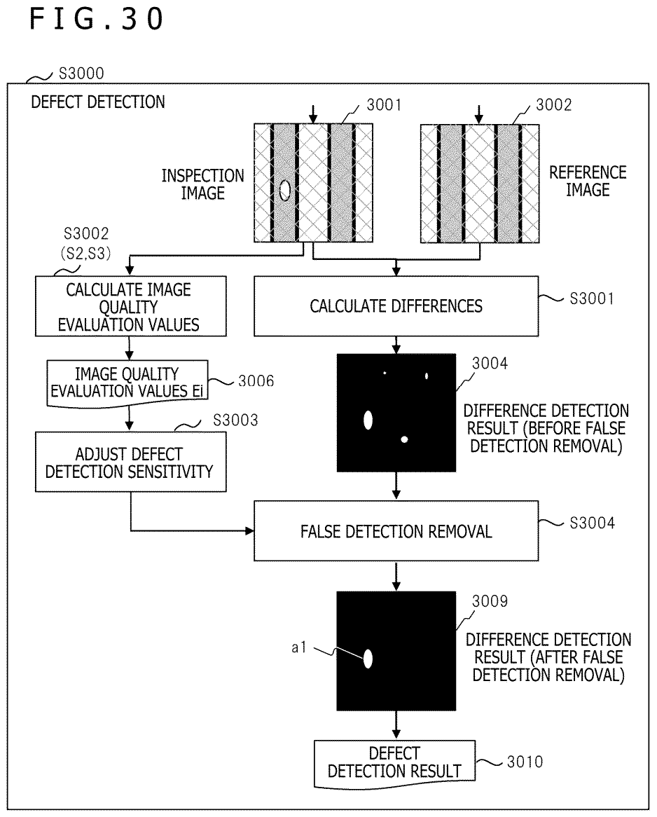

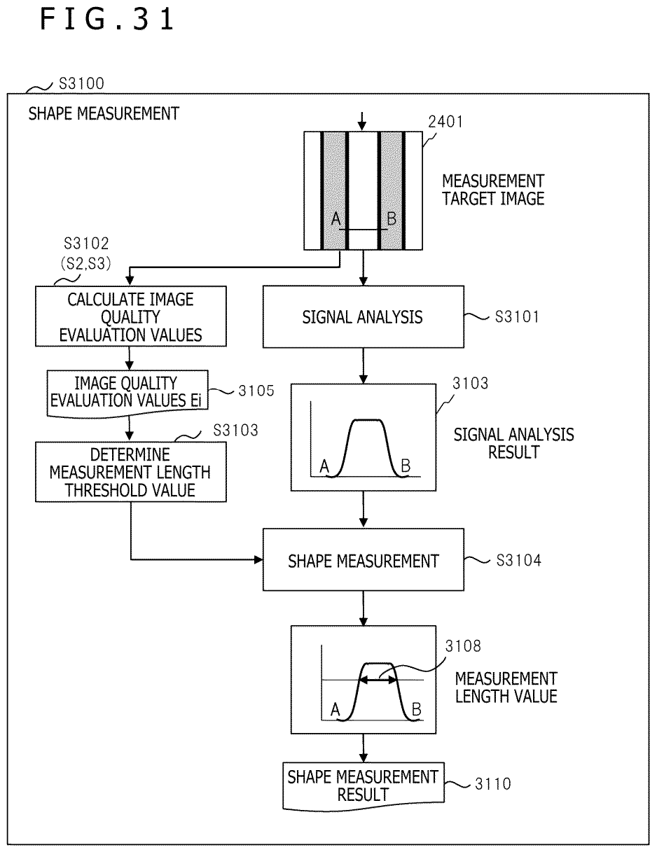

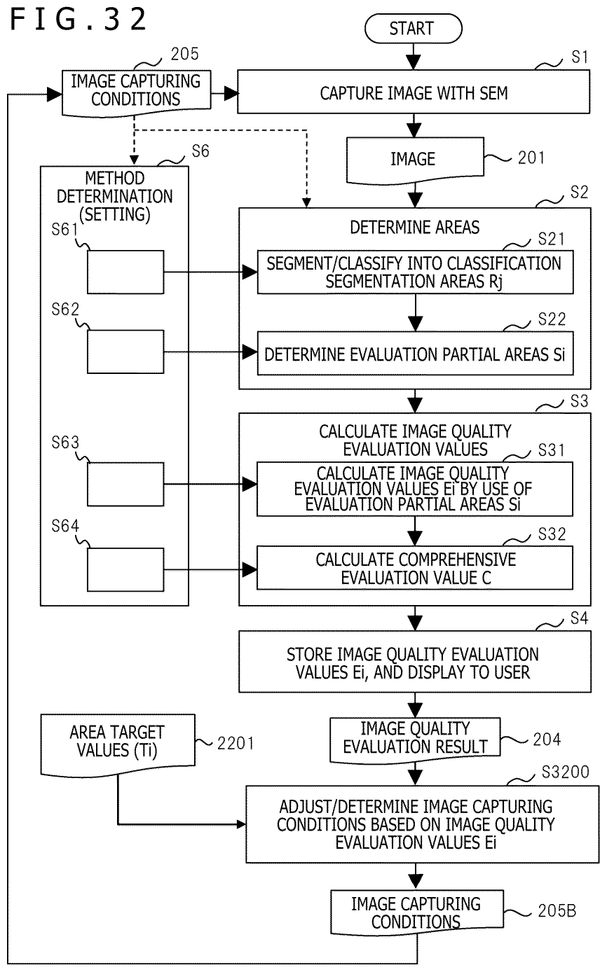

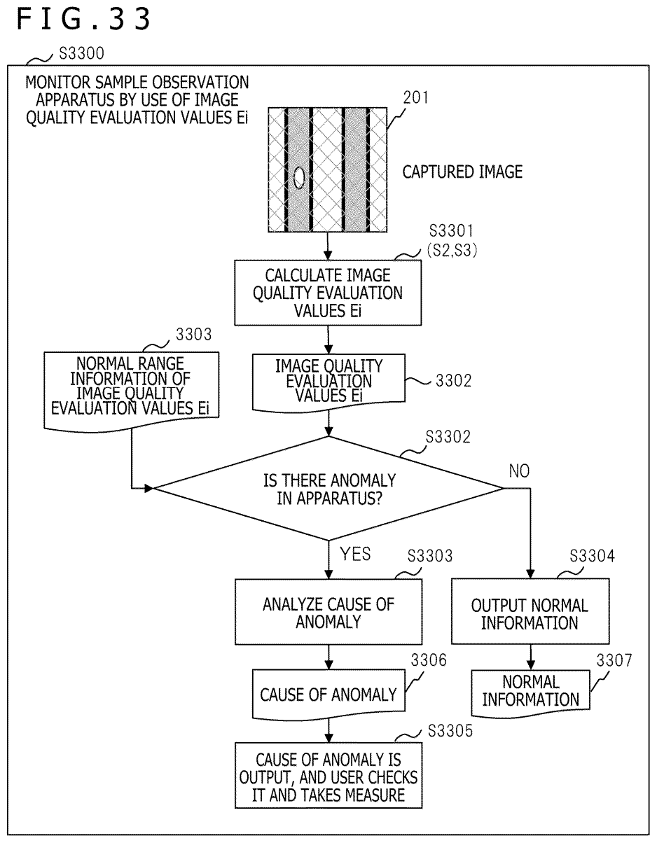

The image quality evaluation values Ei or the comprehensive evaluation value C calculated at Step S3 in FIG. 2 can be used in various manners. The following are use examples of the image quality evaluation values Ei and the comprehensive evaluation value C. Details of each of them are mentioned later.
(Example 1) Adjustment/determination of parameters P of an image quality enhancement process (image quality enhancement engine (FIG. 21)
(Example 2) Correction of evaluation partial areas (FIG. 28)
(Example 3) Benchmarking (comparison of image quality between images) (FIG. 29)
(Example 4) Defect detection (FIG. 30)
(Example 5) Shape measurement (FIG. 31)
(Example 6) Determination of image capturing conditions (FIG. 32)
(Example 7) Apparatus monitoring (FIG. 33)

In the sample observation system and method of the first embodiment, at least one functionality corresponding to the use examples described above is implemented. It is assumed that, in a case where a plurality of functionalities are implemented, the user can select the functionalities by user setting and the like, to make the functionalities available.

### [Adjustment/Determination of Parameters P of Image Quality Enhancement Process]

Adjustment/determination of parameters P of an image quality enhancement process (image quality enhancement engine) using image quality evaluation values Ei is explained using FIG. 21 and the like. One of features of the first embodiment is that there may be a step of determining parameters P of an image quality enhancement engine on the basis of image quality evaluation values Ei and a step of heightening the quality of an image by using the image quality enhancement engine based on the determined parameters P.

There has been a problem that, since image quality output with certain parameters cannot be quantified in parameter adjustment of an image quality enhancement engine, it is not possible to judge the superiority/inferiority of the output image quality, and parameter adjustment is difficult. In this regard, in the first embodiment, since quantification of image quality becomes possible by using image quality evaluation values Ei, and the superiority/inferiority of image quality can be judged on the basis of the magnitudes of the image quality evaluation values Ei, parameters of an image quality enhancement engine are adjusted on the basis of the image quality evaluation values Ei. Thus, the parameters of the image quality enhancement engine that outputs an image with superior quality can be determined.

First, FIG. 21 depicts a configuration example of an overall procedure and functional blocks, including an image quality enhancement process (image quality enhancement engine) and calculation of image quality evaluation values Ei mentioned before. FIG. 21 particularly depicts adjustment/determination of parameters P of an image quality enhancement process (corresponding image quality enhancement engine) using image quality evaluation values Ei. First, as depicted on the left side, Step S2101 of inputting a target image 201 and calculating image quality evaluation values Ei is similar to Steps S2 and S3 in FIG. 2 mentioned before. As a result of Step S2101, the image quality evaluation result 204 including the image quality evaluation values Ei is obtained.

In a case where the computer system 3 performs image quality heightening, in other words, image quality enhancement, of the target image 201, the computer system 3 performs the image quality enhancement process using the image quality enhancement engine at Step S2100. As a result of Step S2100, an image 2101 which is a quality-heightened image (i.e., a quality-enhanced image) is obtained. The image quality enhancement process at Step S2100 is, for example, a process for enhancing the resolution or the S/N (signal/noise ratio). As an example, in an image restoration process, a clear image with a high S/N is obtained by estimation from a captured image such that resolution degradation and noise superimposition are removed.

Regarding the image quality enhancement engine of the image quality heightening process at Step S2100, for example, the computer system 3 includes a rule-based image quality enhancement engine 2100A and a machine-learning image quality enhancement engine 2100B. At Step S2100, the computer system 3 performs the image quality heightening process using the image quality enhancement engine by a method selected in setting of Step S6 in FIG. 6 from the image quality enhancement engines. While the image quality enhancement engines of the two schemes are included in the present example, this is not the sole example. In one possible form, only an image quality enhancement engine of one scheme is included, depending on the system.

The image quality enhancement process by the image quality enhancement engine at Step S2100 has one or more parameters forming the image quality enhancement process, and the parameters (i.e., image quality enhancement process parameters) are denoted by P. A plurality of the parameters P are denoted by Pi (i=1 to Np). Np is the number of parameters.

When the rule-based image quality enhancement engine 2100A is used at Step S2100, image processing parameters are used as the parameters P. When the machine-learning image quality enhancement engine 2100B is used, machine learning model parameters, for example, parameters of a CNN, are used as the parameters P.

When the image quality enhancement process using the image quality enhancement engine at Step S2100 is performed, if it is performed for the first time, the image quality enhancement process is performed in accordance with setting information 2110 concerning the image quality enhancement process which information includes the parameters P set at Step S6 (setting step) in FIG. 6.

Further, the computer system 3 may calculate image quality evaluation values Ei at Step S2101 by using the image 201 or the image 2101, which is a quality-heightened image, and may adjust/determine the parameters P of the image quality enhancement process at Step S2102 by using the calculated image quality evaluation values Ei. In the present example, the computer system 3 tentatively obtains the image 2101, which is a quality-heightened image, thereafter calculates image quality evaluation values Ei of the image 2101, and adjusts/determines the parameters P at Step S2102. As a result of Step S2102, adjusted parameters P 2104 are obtained. In the adjustment at Step S2102, the adjusted parameters P 2104 are obtained on the basis of the setting information 2110 concerning the parameters P. The setting information 2110 including the parameters P may be updated with the adjusted parameters P 2104.

In a case where the adjusted parameters P 2104 have been obtained at Step S2102, the image quality enhancement process is performed at Step S2100 on the input image 201 by use of the adjusted parameters P 2104, and as a result, the image 2101, which is a quality-heightened image, is obtained.

In the first embodiment, there is a functionality (in particular, Step S2102) of adjusting/determining the parameters P 2104 of the image quality enhancement process at Step S2100 as in FIG. 21 described above such that the parameters P 2104 become more preferable values, that is, such that the image 2101 has more preferable image quality.

For example, it is assumed that, as a result of checking, at Step S2101, the image quality evaluation value E1 related to the sharpness of edges of the image 2101 obtained as a result of the image quality enhancement process by the rule-based image quality enhancement engine 2100A at Step S2100, a small value is output as the sharpness (i.e., the sharpness is evaluated as being not good). In this case, as adjustment of the parameters P of the image quality enhancement process, at Step S2102, the computer system 3 selects such a parameter P that increases the number of times of an image restoration process for blur removal or such a parameter P as to intensify an edge emphasis process. The parameters P thus adjusted are applied to the image quality enhancement process at Step S2100. By thereafter performing the image quality enhancement process at Step S2100 with the adjusted parameters P on the image 201 which is the one on which the image quality enhancement process has been performed for the first time (or on another subsequent image), the computer system 3 can obtain an image 2101 with its quality (e.g., sharpness) enhanced as compared to the last time.

The computer system 3 repeats Step S2100 of image quality enhancement, Step S2101 of calculation of image quality evaluation values Ei, and Step S2102 of adjustment/determination of parameters P as in FIG. 21 as necessary. By such a cycle, the parameters P 2104 of the image quality enhancement process can be optimized such that an image 2101 with quality as desired by the user can be obtained as a result of the image quality enhancement process at Step S2100.

While the computer system 3 calculates one or more image quality evaluation values Ei at Step S2101 and adjusts the parameters P by using the image quality evaluation values Ei in the example described above, this is not the sole example. As with Step S32 mentioned before, at Step S2101, the computer system 3 may calculate the comprehensive evaluation value C (e.g., the comprehensive evaluation value C taking into consideration the image quality enhancement process) and adjust the parameters P by using the comprehensive evaluation value C.

Note that examples of parameters P of an image quality enhancement process (e.g., an image restoration process) according to the image capturing conditions 205 of an image 201 include a chromatic aberration coefficient, a spherical aberration coefficient, and the like.

### [Adjustment/Determination of Parameters P by Use of Target Values of Ei]

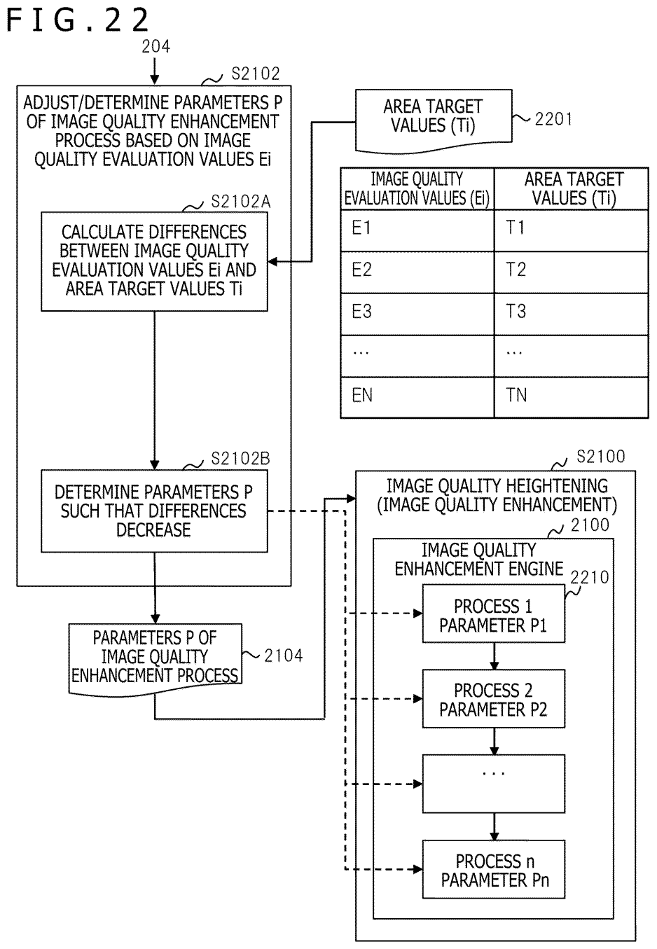

A method of using target values (written as area target values 2201) of image quality evaluation values Ei at Step S2102 of adjustment/determination of parameters P in FIG. 21 described above is explained using FIG. 22. One of features of the first embodiment is that the computer system 3 may set individual area target values 2201 for some or all of a plurality of image quality evaluation values Ei, and adjust/determine the parameters P of the image quality enhancement process such that the image quality evaluation values Ei approach the area target values 2201.

There is a problem that, even if an image with quality that maximizes image quality evaluation values Ei (in the case of the definition that the greater the values of Ei are, the better the image quality is) or that minimizes image quality evaluation values Ei (in the case of the definition that the smaller the values of Ei are, the better the image quality is) is generated/output at Step S2100 of image quality heightening, an image with quality desired by the user cannot be obtained in some cases. For example, in a case where the degree of noise suppression of noise generated in an image is set as one (the image quality evaluation value E3 in FIG. 4) of image quality evaluation values Ei, the image quality evaluation value Ei becomes the best in an image without noise. However, since noise is generated in images that the user usually uses for observation, there is a possibility that an image with the best image quality evaluation value Ei is judged as being unnatural. In view of this, in the first embodiment, the computer system 3 sets individual area target values for some or all of the image quality evaluation values Ei, and adjusts/determines the parameters P such that the image quality evaluation values Ei approach the area target values.

FIG. 22 is a diagram for explaining adjustment/determination of the parameters P of the image quality enhancement process, by use of area target values which are target values of image quality evaluation values Ei, as a detailed process example related to Step S2102 in FIG. 21 or as a modification example. Specifically, Step S2102 has Steps S2102A and S2102B. Here, area target values for the respective image quality evaluation values Ei are denoted by Ti.

First, as depicted in FIG. 21, the computer system 3 generates/outputs an image 2101 which is a result of the image quality enhancement process at Step S2100 from an image 201 captured for observation. The computer system 3 calculates image quality evaluation values Ei of the image 2101 at Step S2101 by using the image 2101 as an input, and obtains the image quality evaluation result 204. Thereafter, at Step 2102A in Step S2102, the computer system 3 calculates the differences between the image quality evaluation values Ei and preset area target values Ti 2201. These differences are differences of the respective image quality evaluation values Ei. Then, at Step S2102B, the computer system 3 adjusts/determines the parameters P 2104 of the image quality enhancement process such that the differences decrease. At Step S2102B, adjustments may be made to make the differences smaller than a threshold value, or adjustments may be made to make the differences obtained this time smaller than the differences obtained last time. The computer system 3 repeats such a series of processing, and stores/outputs such parameters P that minimize the differences between the image quality evaluation values Ei and the area target values Ti 2201 as much as possible.

In addition, FIG. 22 depicts an example of area target values Ti in a table. This table has a column of image quality evaluation values Ei and a column of area target values Ti. Data of such setting information concerning the area target values Ti 2201 may be managed to be included as part of the image quality evaluation value information 203 mentioned before.

In addition, FIG. 22 illustrates a configuration example of the image quality enhancement process by an image quality enhancement engine 2100 at Step S2100. In this example, the image quality enhancement engine 2100 is configured to sequentially perform a plurality of processes (process 1 to process n) 2210 as expressed as a procedure, and has parameters P (P1 to Pn) related to the respective processes 2210. At Step S2102, the computer system 3 may determine the values of the respective parameters P.

Regarding a setting method of the area target values 2201, the user may input/set the area target values 2201 directly on a GUI screen as part of Step S6 of setting in FIG. 6. Alternatively, a method in which the computer system 3 automatically sets the area target values 2201 may be applied. Examples of the method include a method in which calculated image quality evaluation values Ei of images that satisfy image quality desired by the user and have appearance similar to that of images 201 for observation are automatically set as the area target values 2201.

While target values of image quality evaluation values Ei are used in the case depicted in the example described above, similarly, a method in which a target value (comprehensive target value) is set for the comprehensive evaluation value C and parameters P are determined using the target value of the comprehensive evaluation value C is also possible.

### [Adjustment/Determination of Parameters P by Use of Comprehensive Evaluation Value C]

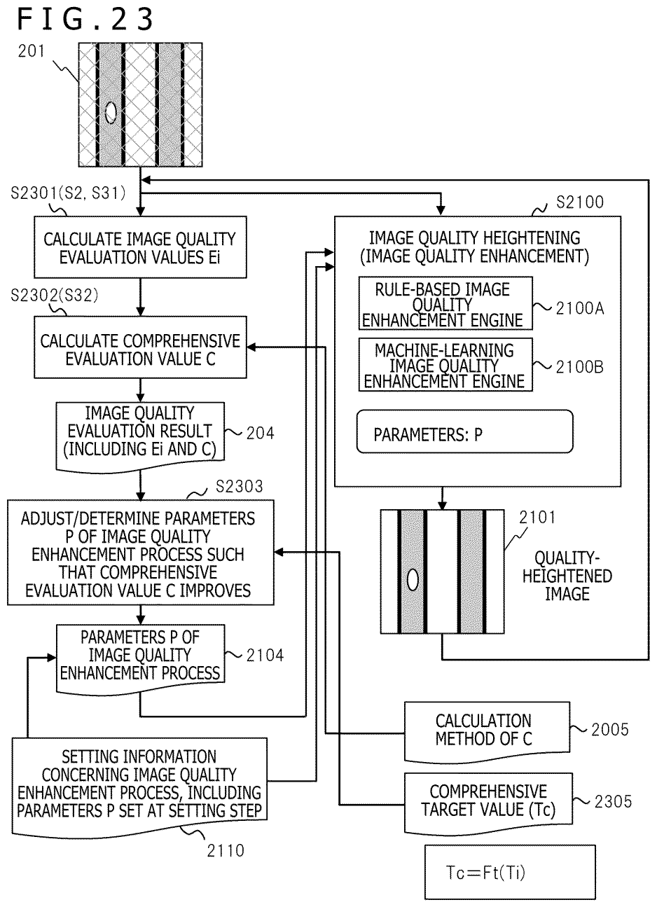

A method of adjusting/determining parameters P of the image quality enhancement process at Step S2102 in FIG. 21 by use of the comprehensive evaluation value C calculated at Step S32 in FIG. 2 (specifically, FIG. 20) is explained using FIG. 23. One of features of the first embodiment is that, at Step S2102 in FIG. 21, the parameters P of the image quality enhancement process may be adjusted/determined such that the value of the comprehensive evaluation value C is improved.

There is a problem that it is desired to determine preferable parameters P of the image quality enhancement process also in a case where a plurality of image quality evaluation values Ei are taken into consideration comprehensively, in a case where emphasis is placed on image quality evaluation values Ei related to particular image quality items in a plurality of image quality evaluation values Ei, or in other similar cases. In this regard, in the first embodiment, the parameters P of the image quality enhancement process are adjusted/determined in such a manner as to improve the value of the comprehensive evaluation value C. In particular, the parameters P of the image quality enhancement process are adjusted/determined in such a manner as to improve the value of the comprehensive evaluation value C calculated using priorities of image quality evaluation values Ei mentioned before.

FIG. 23 is an explanatory diagram related to adjustment/determination of the parameters P of the image quality enhancement process by use of the comprehensive evaluation value C. FIG. 23 depicts a procedure obtained by modifying FIG. 21. The computer system 3 first generates/outputs an image 2101 having quality heightened at Step S2100 from an image 201 captured for observation. Next, the computer system 3 calculates image quality evaluation values Ei of the image 2101 at Step S2301 (corresponding to Steps S2 and S31 mentioned before). Next, at Step S2302 (corresponding to Step S32 mentioned before), the computer system 3 calculates the comprehensive evaluation value C formed by combining the calculated image quality evaluation values Ei described above, on the basis of the calculation method 2005 (FIG. 20) of the comprehensive evaluation value C. The calculated comprehensive evaluation value C is included in the image quality evaluation result 204 along with the image quality evaluation values Ei.

Next, at Step S2303, the computer system 3 adjusts/determines the parameters P 2104 of the image quality enhancement process (Step S2100) such that the value of the comprehensive evaluation value C described above improves. At Step S2302, adjustments may be made to make the C value smaller than a threshold value, or adjustments may be made to make the C value obtained this time smaller than the C value obtained last time. By repeating such a series of processing, the computer system 3 determines such parameters P 2104 that make it possible to generate/output an image 2102 with quality that makes the comprehensive evaluation value C the best as much as possible.

In addition, as in the example in FIG. 22, in the example in FIG. 23, a comprehensive target value 2305 which is a target value may be set also for the comprehensive evaluation value C, and the parameters P may be adjusted/determined in such a manner as to make the difference between the comprehensive evaluation value C and the comprehensive target value 2305 smaller at Step S2303. As with area target values 2201, in the setting of the comprehensive target value 2305, the user may input/set the comprehensive target value 2305 directly on a GUI screen. Alternatively, as with area target values 2201, a method in which the computer system 3 automatically sets the comprehensive target value 2305 may be applied. In addition, in the setting of the comprehensive target value 2305, the comprehensive target value 2305 formed by combining area target values 2201 may be set. Assuming that the comprehensive target value 2305 is Tc, Tc can be defined by a function Ft(Ti) of area target values Ti.

### [Rule-Based Image Quality Enhancement Engine]

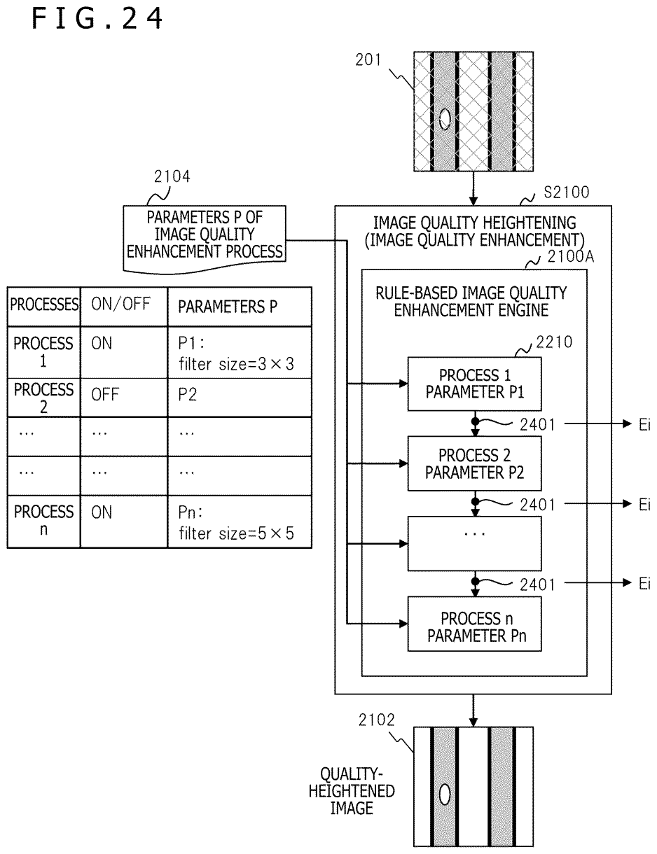

A method in a case where the image quality enhancement engine (the image quality enhancement engine 2100 in FIG. 21) at Step S2100 in the image quality enhancement process in FIG. 21 is the image quality enhancement engine 2100A configured using rule-based image processing is explained using FIG. 24. In this case, the parameters P 2104 of the image quality enhancement process are image processing parameters of the image quality enhancement engine 2100A.

There has been a problem that, in a case where it is attempted to heighten image quality by using a machine-learning image quality enhancement engine, it is difficult to finely adjust output image quality with an image quality enhancement engine using a trained model. In this regard, in the first embodiment, it becomes possible to finely adjust the image quality of an image 2102 obtained after the image quality enhancement process in a case where the rule-based image quality enhancement engine 2100A is used.

FIG. 24 is a diagram for explaining the rule-based image quality enhancement engine 2100A. In the present example, the computer system 3 obtains an image 2102 as a result of performing the image quality enhancement process using the rule-based image quality enhancement engine 2100A on an image 201 captured for observation. The n processes 2210 (process 1 to process n) designed in advance are implemented on the image quality enhancement engine 2100A (as in FIG. 22). Examples of the processes 2210 include a shading correction process, a noise removal process, an image restoration process, and the like.

As depicted in a table in FIG. 24, the computer system 3 sets ON (to perform)/OFF (not to perform) and the values of the parameters P (P1 to Pn) for the n respective processes 2210 in the parameters P 2104 of the image quality enhancement process. In the present example, for the target image 201, ON is set for the process 1, which is a filtering process, and 3×3 is set for the filter size as the parameter P1 of the process 1. Meanwhile, OFF is set for the process 2. Accordingly, in the case of setting of the parameters P, the process 2 is not performed at the time of the image quality enhancement process at Step S2100 on the image 201.

As a modification example, the following may be performed. In the example in FIG. 24, the rule-based image quality enhancement engine 2100A generates an intermediate image 2401 between each pair of processes 2210 in the plurality of processes 2210. For example, a first intermediate image 2401 is generated as an output of the process 1, and a second intermediate image 2401 is generated as an output of the process 2. As also depicted in FIG. 24, in the modification example, the computer system 3 may calculate image quality evaluation values Ei of the intermediate images 2401 generated in the middle of the image quality enhancement process by the image quality enhancement engine 2100A. Moreover, image quality evaluation values Ei of intermediate images 2401 generated in a particular plurality of processes may be calculated. Examples include calculation of image quality evaluation values Ei of intermediate images 2401 generated by executing only the process 2 and the process 3. Setting for this also can be made at Step S6. For example, it is possible to set which image quality evaluation values Ei are calculated for intermediate images 2401 of which processes 2210. The image quality evaluation values Ei thus calculated can be used for adjustment/determination of the parameters P as with the manner mentioned before.

### [Machine-Learning Image Quality Enhancement Engine]

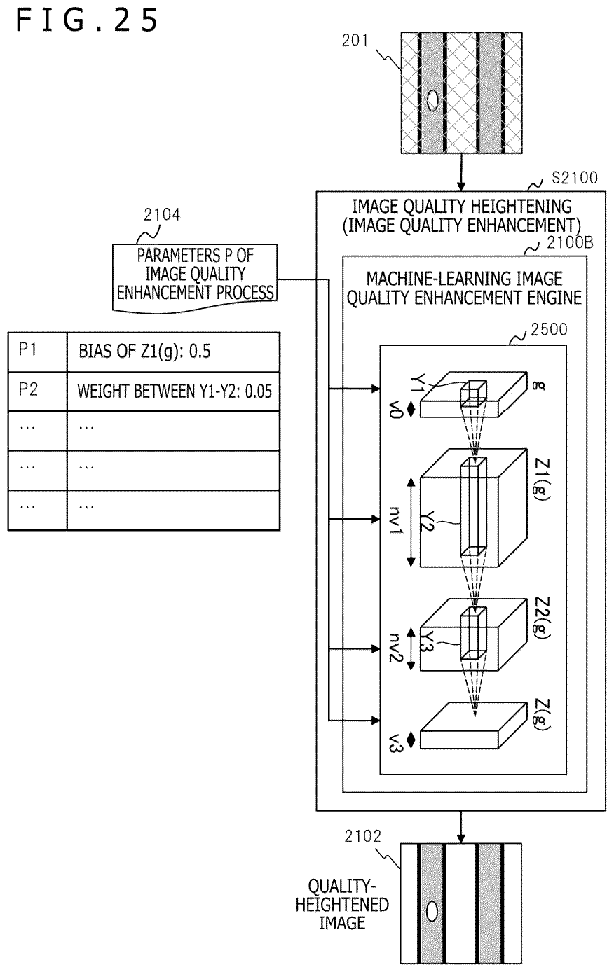

A method in a case where the image quality enhancement engine at Step S2100 in FIG. 21 is the image quality enhancement engine 2100B configured using machine-learning image processing given by a CNN, for example, is explained using FIG. 25. In this case, for example, the parameters P 2104 of the image quality enhancement process are model parameters such as weights (i.e., coupling coefficients) between nodes of a network of the CNN or biases.

There is a problem that it is difficult in some cases to design in advance a process required for image quality enhancement. Since there are diverse variations of the appearance of semiconductor patterns which are treated as targets in observation images, it is difficult to design a rule-based image quality enhancement engine that can cope with all observation images. In this regard, in the first embodiment, for example, it becomes possible to cope with all observation images by using the image quality enhancement engine 2100B configured using machine-learning image processing given by a CNN.

FIG. 25 is an explanatory diagram related to the machine-learning image quality enhancement engine 2100B. In the present example, the computer system 3 obtains an image 2102 as a result of performing the image quality enhancement process using the machine-learning image quality enhancement engine 2100B on an image 201 captured for observation. In the present example, as a machine learning model 2500, a CNN having a triple-layer structure is applied to the machine-learning image quality enhancement engine 2100B. The CNN model 2500 calculates intermediate pieces of data Z1(g) and Z2(g) and an estimation result Z(g) of an input image g, and outputs the estimation result Z(g) as the image 2102, which is a quality-heightened image. The computer system 3 sets model parameters of the model 2500 of the image quality enhancement engine 2100B in the parameters P 2104 of the image quality enhancement process. In the present example, as depicted in the table, the bias of Z1(g) is set to 0.5, and the weight between Y1 and Y2 is set to 0.05 in the parameters P 2104.

Note that the configuration of the neural network of the image quality enhancement engine 2100B is not limited to the example described above, and other configurations may be applied. For example, the number of layers of the CNN may be changed, a network with four layers or more or the like may be used, or a configuration having a skip connection may be adopted.

In adjustment/determination (Step S2102 in FIG. 21) of the parameters P 2104 of the machine-learning image quality enhancement engine 2100B, for example, image quality evaluation values Ei or the comprehensive evaluation value C are/is used as a loss function at the time of learning of the model 2500. As a result, model parameters to enhance image quality can be determined efficiently.

### [Correction of Evaluation Partial Areas]

Next, a functionality to correct evaluation partial areas Si is explained. After displaying image quality evaluation values Ei to the user on a GUI screen at Step S4 in FIG. 2, the computer system 3 performs user setting including area correction (which means correction of evaluation partial areas Si) according to user operation. The computer systems 3 uses, as input information of Step S6 (in particular, Steps S21 and S22) of setting, the user setting information 202 that is obtained by the user setting and includes area correction information. Then, by setting at Step S6, the processing contents of Steps S21 and S22 are determined to become more preferable. By such a cycle, evaluation partial areas Si determined at Step S22 are optimized, and as a result, more preferable image quality evaluation values Ei can be calculated.

FIG. 28 depicts a procedure including Step S7 of user setting of respective functionalities, Step S7 including a functionality to correct evaluation partial areas Si. The procedure in FIG. 28 is configured on the basis of the procedure in FIG. 2. In the procedure in FIG. 28, on the basis of image quality evaluation values Ei obtained at Steps S1, S2, and S3 mentioned before, at Step S4, the image quality evaluation values Ei and the like are displayed on a GUI screen, and Step S7 of user setting is provided thereafter. At Step S7, the computer system 3 provides a GUI screen for user setting, the user uses respective functionalities related to setting by performing input operation while looking at the GUI screen, and results of the user setting are stored as the user setting information 202.

As examples of functionalities, Step S7 in FIG. 28 has Step S71 of setting image quality evaluation values Ei, Step S72 of correcting evaluation partial areas Si, and Step S73 of benchmarking (comparison of image quality between images) mentioned later. The user can use functionalities selected on the GUI screen. Step S71 corresponds to a functionality to allow the user to check/set image quality evaluation information 203 as in FIG. 3 mentioned before. This functionality includes a functionality (Step S65 in FIG. 6) to additionally set image quality evaluation values Ei mentioned before. Step S72 corresponds to the area correction functionality described above. The user setting information 202 (here, including the image quality evaluation information 203) which is a result of Step S7 is used for setting at Step S6 in FIG. 6.

### [GUI (1)]

First, an example of a GUI related to user setting (Step S7), displaying of image quality evaluation values Ei (Step S4), and the like in the sample observation system of the first embodiment is explained.

In the first embodiment, a target image 201, evaluation partial areas Si, image quality evaluation values Ei, and the like are displayed to the user on a GUI screen. Further, in the first embodiment, as a GUI supporting the area correction functionality described above, a GUI that allows the user to manually correct the evaluation partial areas Si is provided on the GUI screen. In addition, in the first embodiment, a GUI that enables user setting of internal parameters Qi_m (FIG. 16), area target values Ti (FIG. 22), and the like mentioned before is provided.

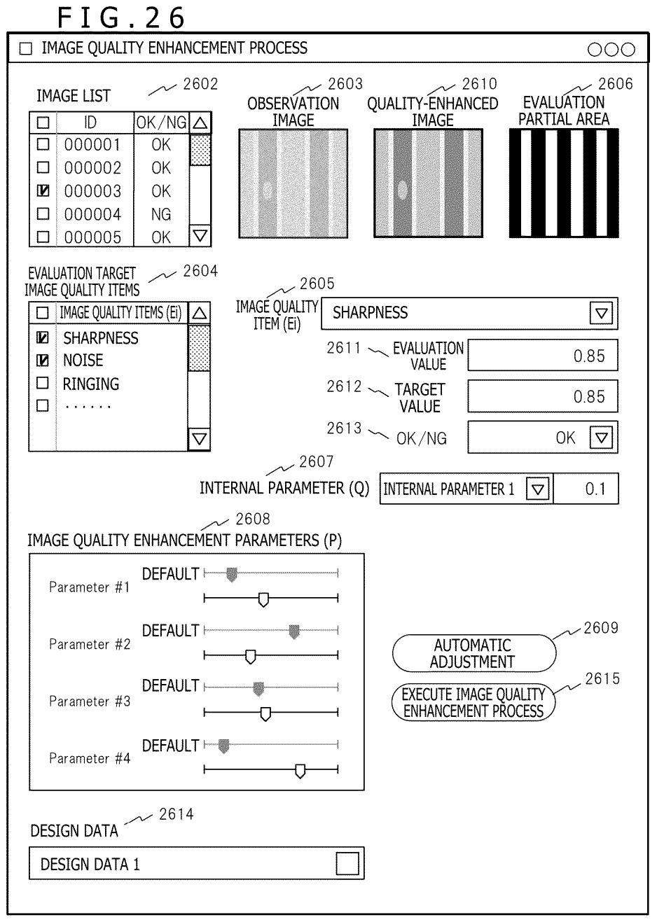

FIG. 26 depicts an example of the GUI screen including the GUIs described above. The screen in FIG. 26 is an example of the GUI screen related to Step S2101 (FIG. 21) of the image quality enhancement process and functionalities related thereto. The screen in FIG. 26 has an interface area (image list field) 2602, an interface area (observation image field) 2603, an interface area (evaluation target image quality item field) 2604, an interface area (image quality item field) 2605, an interface area (evaluation partial area field) 2606, an interface area (internal parameter field) 2607, an interface area (image quality enhancement parameter field) 2608, an interface area (quality-enhanced image field) 2610, an interface area (evaluation value field) 2611, an interface area (target value field) 2612, an interface area (OK/NG field) 2613, and the like.

In the interface area (image list field) 2602, a list of images 201 (written as observation images here) captured at Step S2 (FIG. 2) of image capturing is displayed. In the interface area (observation image field) 2603, an observation image with an ID selected in the list is displayed.

In the interface area (evaluation target image quality item field) 2604, a list of image quality evaluation values Ei corresponding to evaluation target image quality items is displayed. In this list, the user can determine image quality evaluation values Ei corresponding to evaluation target image quality items of a target image by making selection using check boxes, for example. It becomes possible to designate, in the interface area 2605, the image quality evaluation values Ei corresponding to the image quality items selected using the check boxes. In the interface area (image quality item field) 2605, for example, when the user operates a list box, the image quality evaluation values Ei are displayed as choices, and the user can select a desired image quality evaluation value Ei. The image quality evaluation value Ei of the image quality item selected in the interface area 2605 is treated as the target of the interface area 2603, the interface area 2610, the interface area 2606, and the like.

In the interface area (evaluation partial area field) 2606, an evaluation partial area Si (one determined at Step S22) used for calculation of the image quality evaluation value Ei selected in the interface area 2605 is displayed.

In the interface area (internal parameter field) 2607, internal parameters Qi_m of the selected image quality evaluation value Ei are displayed. In the interface area 2607, for example, when the user operates a list box, an internal parameter Qi_m to be displayed can be selected, and the parameter value (e.g., “0.1”) of the internal parameter Qi_m is displayed.

In the interface area (image quality enhancement parameter field) 2608, adjustment and setting by manual operation by the user can be performed regarding adjustment and setting of the parameters P 2104 of the image quality enhancement engine (Step S2100 in FIG. 21). In the interface area 2608, for example, a slider is displayed for each individual parameter P in the parameters P 2104 of the image quality enhancement engine. By changing the positions of the sliders, the user can adjust the values of the respective parameters P (e.g., #1 to #4). In addition, a default value of each parameter P is indicated by a gray slider.

When the user presses an interface area (image quality enhancement process execution button) 2615, the image quality enhancement process (Step S2100) using the values of the parameters P indicated by the sliders in the interface area 2608 is started. An image 2102 which is a quality-enhanced image generated/output by the image quality enhancement process is displayed in the interface area (quality-enhanced image field) 2610. The user can check the observation image in the interface area 2603, the quality-enhanced image in the interface area 2610, and the evaluation partial area Si in the interface area 2606 by visually comparing them.

In addition, when the user presses an interface area (automatic adjustment button) 2609, the computer system 3 executes automatic adjustment of the parameters P 2104 of the image quality enhancement engine (Step S2100) and adjusts/determines the parameter values. Depending on the values of the adjusted parameters P, the positions of the sliders of the parameters P in the interface area 2608 are changed automatically. The image 2102 with quality heightened by the image quality enhancement engine using the automatically adjusted parameters P is displayed in the interface area 2610.

The value of the image quality evaluation value Ei of the image quality item designated in the interface area 2605 regarding the quality-enhanced image in the interface area 2610 is displayed in the interface area (evaluation value field) 2611. Moreover, an area target value Ti related to the image quality evaluation value Ei is displayed in the interface area (target value field) 2612. The user checks the quality-enhanced image in the interface area 2610, the image quality evaluation value Ei in the interface area 2611, and the area target value Ti in the interface area 2612, and judges whether or not a quality-enhanced image with satisfactory quality has been obtained (whether the image is OK or NG). The user inputs/selects a result of the judgment in the interface area (OK/NG field) 2613.

In addition, in an interface area (design data field) 2614, the design data 206 (FIG. 6) to be used in classification (Step S21 in FIG. 2) of classification segmentation areas Rj necessary for determining evaluation partial areas Si can be designated.

### [GUI (2)]

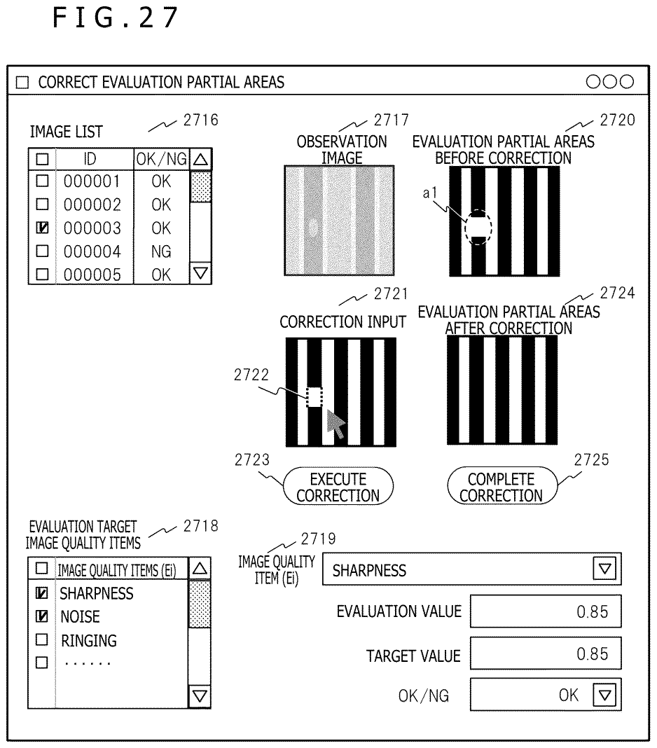

Next, FIG. 27 depicts an example of a GUI screen related to a functionality to correct evaluation partial areas Si. The screen in FIG. 27 has a GUI related to correction of evaluation partial areas Si and has an interface area 2716, an interface area 2717, an interface area 2718, an interface area 2719, an interface area 2720, an interface area 2721, an interface area 2724, and the like. Note that the screen in FIG. 27 may be integrated with the screen in FIG. 26 or may be another GUI to be displayed after transition.

There is a possibility that areas expected by the user are not determined as evaluation partial areas Si due to the influence of the structure of a semiconductor pattern, the size of a defective area occupying an image, and the like. To cope with this, in that case, evaluation partial areas Si can be corrected (i.e., manually corrected) on the basis of input operation by the user using the screen in FIG. 27.

In the interface area (inspection image list field) 2716, a list of images 201 (observation images) captured at Step S1 (FIG. 2) of image capturing is displayed. An observation image with an ID selected by the user in this list is displayed in the interface area (observation image field) 2717. In the interface area (evaluation target image quality item field) 2718, a list of image quality evaluation values Ei corresponding to evaluation target image quality items is displayed. In the interface area (image quality item field) 2719, with image quality evaluation values Ei selected in the interface area 2718 as choices, an image quality evaluation value Ei selected by the user is displayed. These fields have functionalities similar to those of the respective corresponding fields in FIG. 26.

In the interface area (before-correction evaluation partial area field) 2720, an evaluation partial area Si before correction is displayed. In this field, an evaluation partial area Si (one determined at Step S22) to be used for calculation of the image quality evaluation value Ei selected in the interface area 2719 is displayed.

The user designates, in the interface area 2719, an evaluation target image quality item corresponding to an evaluation partial area Si that she/he wants to correct. In the interface area 2720, an evaluation partial area Si to be used for calculation of an image quality evaluation value Ei corresponding to the image quality item selected in the interface area 2719 is displayed. It is assumed in the present example that the evaluation partial area Si has a portion where two adjacent line patterns are connected in the horizontal direction, as a portion al represented by a broken line, in vertical line patterns (white portions), and that the portion is a portion the user wants to correct. This portion al corresponds to a portion that appears to be a defective area in the observation image in the interface area 2717.

In addition, in the interface area (correction input field) 2721, initially, one that is the same as the evaluation partial area Si displayed in the interface area 2720 is displayed as one for correction input. For example, as represented by dotted lines 2722, the user inputs, in the interface area 2721, boundaries of the evaluation partial area Si (white portions) as correction information (i.e., manual correction information), using input equipment such as a mouse. In the present example, at the portion al, the dotted lines 2722 are input in such a manner as to draw new boundaries between vertical line patterns such that the portion connecting the vertical line patterns in the horizontal direction is not included in the evaluation partial area Si. The way of inputting correction information is not limited to this. In another example, a method in which a pixel area to be included in an evaluation partial area Si is painted, a method in which, conversely, a pixel area not to be included in an evaluation partial area Si is painted, and the like may be used.

After inputting the correction information described above, the user presses an interface area (correction execution button) 2723. In response, using the correction information in the interface area 2721, the computer system 3 determines an evaluation partial area Si again (Step S22), and displays the determined evaluation partial area Si in the interface area 2724. In the interface area (after-correction evaluation partial area field) 2724, the evaluation partial area Si after the correction is displayed.

The user checks the evaluation partial area Si after correction in the interface area 2724. In a case where the user judges that the correction has successfully been made, as a result of the checking, the user completes the correction by pressing an interface area (correction completion button) 2725. In a case where the user judges that the correction has not successfully been made, the user inputs correction information by using the interface area 2721 again and performs correction work similarly.

While the user can manually correct boundaries of an evaluation partial area Si regarding determination of a preferable evaluation partial area Si in the example depicted in the present implementation example, this is not the sole example. The user may change parameters of the segmentation technique or the machine learning model at Step S21 of area segmentation/classification (Step S61 in FIG. 6). In addition, the user may change the method of generating an evaluation partial area Si from classification segmentation areas Rj (Step S62 in FIG. 6).

### [Benchmarking Using Image Quality Evaluation Values Ei]

A step (Step S73 in FIG. 28) of benchmarking using image quality evaluation values Ei is explained using FIG. 29. One of features of the first embodiment is that there are a benchmarking step and functionality at and by which, regarding image quality evaluation values Ei of a certain single image quality item, on the basis of a result of comparison between an image quality evaluation value Ei_1 of a first image and an image quality evaluation value Ei_2 of a second image, the superiority/inferiority in image quality of the first image and the second image is judged.

There has been a problem that, conventionally, since a human visually checks/judges the image quality of two images when she/he judges the superiority/inferiority in image quality of the two images, judgment criteria are ambiguous. In this regard, in the first embodiment, quantitative comparison in image quality becomes possible by using image quality evaluation values Ei.

In FIG. 28, at Step S73 of benchmarking, on the basis of the image quality evaluation result 204 including image quality evaluation values Ei, the computer system 3 compares the designated first image and second image by using an image quality evaluation value Ei of a designated image quality item, and outputs a result of the comparison to the user.

FIG. 29 depicts an example of a GUI screen related to Step S73 of benchmarking. The screen in FIG. 29 depicts an example in which two images, a comparison result, and the like are output. The screen in FIG. 29 has such GUIs as a benchmark (i.e., comparison result) 2900, a recommended image 2910, and an observation image selection 2920.

The benchmark 2900 is expressed in a tabular format in which respective image quality evaluation values Ei (E1 to EN) and the comprehensive evaluation value C of each of a first image 2901 and a second image 2902, which are two images to be compared in image quality, are displayed in parallel. The user can visually compare the two images, the respective image quality evaluation values Ei, and the comprehensive evaluation values C in the benchmark 2900.

For example, regarding the image quality evaluation value E1 “sharpness” (FIG. 3), the E1 value of the second image 2902 is greater than the E1 value of the first image 2901. For example, it is defined that the greater the value of E1 is, the better the image quality is. Accordingly, regarding the image quality item “sharpness” evaluated on the basis of the image quality evaluation value E1, the user can judge that the second image 2902 is superior to the first image 290, without being dependent only on visual judgment regarding the two images. The same applies also to other image quality evaluation values Ei.

In addition, similarly, the comprehensive evaluation values C of the first image 2901 and the second image 2902 are compared. Thus, it becomes possible to judge which image has image quality that is comprehensively superior, in terms of the images each as a whole. For example, it is defined that the greater the value of the comprehensive evaluation value C is, the superior the image quality comprehensively is. Since the second image 2902 has a greater comprehensive evaluation value C in the present example, the user can judge that the second image 2902 has comprehensively superior image quality.

In addition, the computer system 3 may have a functionality to judge which image in two images is preferable for use as an observation image, by using the comparison result 2900 at Step S73 of benchmarking described above, and to automatically recommend the image to the user. For example, the computer system 3 judges that the second image 2902 is comprehensively more preferable as an observation image, on the basis of, in particular, the comprehensive evaluation values C in the comparison result 2900. Then, the computer system 3 displays, in the area of the recommended image 2910, whether the first image 2901 and the second image 2902 are each recommended as an observation image or not. At this time, for example, the computer system 3 may determine to “recommend” an image in a case where the comprehensive evaluation value C of the image is equal to or greater than a threshold value, or may determine to “recommend” an image with the highest comprehensive evaluation value C in a plurality of images (two images here).

In a case where the recommendation functionality described above is used, the user checks the superiority/inferiority of an image (e.g., the second image 2902) recommended in the recommended image 2910 on the GUI screen and another image (e.g., the first image 2901), and inputs, as a judgment result, an image to be used as an observation image. For example, in the area of the observation image selection 2920, the user can selectively input information as to which image in the two images is to be used as an observation image. The computer system 3 stores, as the user setting information 202, the image selected for use as an observation image by the user on the GUI screen. On the basis of the user setting information 202, the designated image is to be used as an observation image (an image to be used in the observation processing operation at Step S5 in FIG. 2).

In addition, the computer system 3 inputs the user setting information 202 including the designation of the observation image to Step S63 in Step S6 of setting in FIG. 28. At Step S63, on the basis of the user setting information 202, the computer system 3 automatically determines a calculation method of image quality evaluation values Ei used at Step S31. At that time, the computer system 3 determines a calculation method of image quality evaluation values Ei such that the image quality evaluation values Ei of the image that is determined as an observation image and has superior quality increase.

In addition, the computer system 3 inputs the user setting information 202 including the designation of the observation image described above to Step S64 in Step S6. At Step S64, on the basis of the user setting information 202, the computer system 3 automatically determines a calculation method of the comprehensive evaluation value C used at Step S32. The computer system 3 determines a calculation method of the comprehensive evaluation value C such that the comprehensive evaluation value C of the image that is determined as an observation image and has superior quality increases.

### [Defect Observation Using Image Quality Evaluation Values Ei]

The example in FIG. 2 mentioned before depicts a case where, at Step S5, image quality evaluation values Ei are used for defect observation of an image 201. At Step S5, for example, in a case where image quality evaluation values Ei of an image 201 are sufficiently high, or, for example, in a case where the image quality evaluation values Ei are equal to or greater than a threshold value, the computer system 3 performs defect observation (i.e., defect inspection or defect detection) using the image 201 as an observation image (i.e., an inspection image). For example, an image 201 having the image quality evaluation value E2 “defect visibility” which is sufficiently high is selected as an observation image. A defect is determined/detected in the observation image by a predetermined defect observation scheme (e.g., a scheme in which comparison with a reference image is performed).

A detailed process example of defect observation (Step S5) using image quality evaluation values Ei is explained using FIG. 30. One of features of the first embodiment is that there is a defect detection step of detecting a defect in an image captured of a semiconductor wafer, on the basis of the image quality evaluation values Ei described above.

There has been a problem that, in a case where the quality of an image as a defect detection target has changed, overdetection (i.e., false detection) or overlooking of defects occurs undesirably. In this regard, in the first embodiment, a defect detection process based on image quality evaluation values Ei is performed.

FIG. 30 depicts Step S3000 of defect detection using image quality evaluation values Ei. FIG. 30 depicts an example in which the sensitivity of defect detection is adjusted on the basis of the image quality evaluation values Ei. Using the image quality evaluation values Ei obtained at Steps S2 and S3 mentioned before (and the image quality evaluation result 204 including the image quality evaluation values Ei), the computer system 3 performs the defect detection process at Step S3000, and obtains a defect detection result 3010 which is a result of the defect detection process.

An example of typical defect detection methods is a method in which a defective portion is determined/detected by comparing an inspection image (i.e., a target image, etc.) which is an image captured of a defect occurrence site and a reference image which is an image without a defect site, and checking differences therebetween. Such a method is used in the defect detection process at Step S3000 in FIG. 30.

First, the computer system 3 receives inputs of an inspection image 3001 captured of a defect occurrence site and a reference image 3002 without a defect site, and, at Step S3001, performs difference calculation on those images to thereby obtain and output a difference detection result 3004.

In the difference detection result 3004, a difference generated at the defective site is detected, and simultaneously, differences generated due to the influence of noise and the like are also detected. In view of this, in the first embodiment (FIG. 30), the computer system 3 calculates an image quality evaluation value Ei 3006 of the inspection image 3001 at Step S3002 corresponding to Steps S2 and S3 of calculation of image quality evaluation values in FIG. 2 mentioned before.

Next, the computer system 3 adjusts the sensitivity of defect detection at Step S3002 on the basis of the image quality evaluation value Ei 3006. The sensitivity is sensitivity of determination/detection of defective portions in a defect detection method used in the defect detection process. The sensitivity is not limited to any particular value, but examples of the sensitivity include such parameter values as weights for determination of defective portions based on differences or threshold values for removal of false detections.

In the present example, the defect detection sensitivity adjusted at Step S3002 is used in false detection removal at Step S3004. At Step S3004, the computer system 3 removes false detections on the basis of the sensitivity from the difference detection result 3004 obtained before false detection removal, and outputs a result thereof as a difference detection result 3009 obtained after false detection removal. The defect detection result 3010 is generated/output on the basis of the difference detection result 3009. In the present example, false detections are removed from areas that are included in the difference detection result 3004, are represented by white portions, and are estimated to be defective, and as a result, a defective area al represented by a white portion is detected in the difference detection result 3004.

While the sensitivity of defect detection is adjusted on the basis of image quality evaluation values Ei in the case explained in the present implementation example, instead of this or in addition to this, changes of feature values in defect detection based on image quality evaluation values Ei, changes of preprocessing and postprocessing, and the like may be made.

While the method in which a reference image is used in defect detection is explained in the present implementation example, this is not the sole example. A method in which a reference image is generated by estimation from the inspection image 3001 and the inspection image 3001 is compared with the estimated reference image may be applied. Alternatively, a method in which only the inspection image 3001 is input to a machine learning model and a defect detection result is output as a result of estimation by the model may be applied.

### [Shape Measurement Using Image Quality Evaluation Values Ei]

Shape measurement using image quality evaluation values Ei is explained using FIG. 31. One of features of the first embodiment is that there is a shape measurement step of measuring a shape (i.e., a measurement length value or CD: Critical Dimension) in an image captured of a semiconductor wafer, on the basis of image quality evaluation values Ei.

There has been a problem that, in a case where the quality of an image as a shape measurement target has changed, a signal to be used for measurement changes, and the measurement length value changes undesirably. In this regard, in the first embodiment, shape measurement based on image quality evaluation values Ei is performed.

FIG. 31 depicts Step S3100 of shape measurement using image quality evaluation values Ei. The present implementation example depicts an example in which, at Step S3100 of shape measurement in FIG. 31, a measurement length threshold value of image shape measurement is adjusted on the basis of image quality evaluation values Ei obtained as results of Steps S2 and S3 in FIG. 2 mentioned before. The computer system 3 receives an input of a measurement target image 3101, and performs shape measurement by analyzing signals of measurement points in the image 3101. The length of a wire width between A and B in the image 3101 is measured in the case explained in the present example.

First, at Step S3101 of signal analysis, the computer system 3 analyzes signals (i.e., a profile) between A and B in the image 3101 and generates/outputs a signal analysis result 3103.

Next, the computer system 3 calculates an image quality evaluation value Ei 3105 of the image 3101 at Step S3102 corresponding to Steps S2 and S3 of calculation of image quality evaluation values in FIG. 2 mentioned before. Next, on the basis of the image quality evaluation value Ei 3105, the computer system 3 adjusts/determines the measurement length threshold value at Step S3103. Thereafter, at Step S3104, the computer system 3 performs shape measurement using the determined measurement length threshold value on the signal analysis result 3103, and, as a result of this, generates/outputs a shape measurement result 3110 including a measurement length value 3108.

While the measurement length threshold value of shape measurement is adjusted on the basis of image quality evaluation values Ei in the example explained in the present implementation example, this is not the sole example. Changes of feature values in shape measurement based on image quality evaluation values Ei, changes of preprocessing and postprocessing, and the like may be made.

### [Adjustment of Image Capturing Conditions by Use of Image Quality Evaluation Values Ei]

Adjustment of image capturing conditions by use of image quality evaluation values Ei is explained using FIG. 32. One of features of the first embodiment is that there is a step of determining image capturing conditions (the image capturing conditions 205 in FIG. 6) of an image 201 on the basis of image quality evaluation values Ei. The computer system 3 adjusts/determines the preferable image capturing conditions 205 by use of image quality evaluation values Ei. In addition, the computer system 3 may determine the image capturing conditions 205 by use of target values (the area target values Ti in FIG. 22) of the image quality evaluation values Ei.

There has been a problem that, since a human needs to visually evaluate image quality when image capturing conditions are adjusted, it takes time and effort for the adjustment. In this regard, in the first embodiment, by quantifying image quality, the necessity for visual evaluation of image quality is eliminated, and time and effort related to adjustment of image capturing conditions are reduced.

FIG. 32 depicts adjustment of the image capturing conditions 205 by use of image quality evaluation values Ei. FIG. 32 is based on FIG. 2 and has some differences. First, using Steps S2 and S3 mentioned before, the computer system 3 calculates image quality evaluation values Ei of an image 201 captured at Step S1 on the basis of the certain image capturing conditions 205, and obtains the image quality evaluation result 204. At Step S4, the computer system 3 may display the image quality evaluation values Ei and the image capturing conditions 205 to the user.

Next, at Step S3200, on the basis of the image quality evaluation values Ei of the image 201, the computer system 3 adjusts/determines (i.e., updates) the image capturing conditions 205 of the image 201. As a result, image capturing conditions 205B after updating are obtained. The image capturing conditions 205B become the new image capturing conditions 205.

At Step S3200, for example, in a case where the value of the image quality evaluation value E5 “degree of dark area emphasis” (FIG. 3) is small, the computer system 3 changes the acceleration voltage as one of parameters of the image capturing conditions 205 to a greater value in order to enhance the visibility of dark areas in the image 201.

The computer system 3 repeats the series of processing in FIG. 32 by use of the image capturing conditions 205B obtained after updating. Thus, the more preferable image capturing conditions 205 for making it possible to capture an image 201 with better quality are determined. In other words, the computer system 3 optimizes the image capturing conditions 205 by causing them to reflect image quality evaluation values Ei.

In adjustment/determination of the image capturing conditions 205 in FIG. 32 as well, as with adjustment of the parameters P of the image quality enhancement engine (FIG. 21) mentioned before, area target values Ti may be set for some or all of a plurality of image quality evaluation values Ei, and the image capturing conditions 205B may be determined such that the image quality evaluation values Ei approach the area target values Ti.

### [Monitoring of Sample Observation Apparatus by Use of Image Quality Evaluation Values Ei]

Monitoring of a sample observation apparatus by use of image quality evaluation values Ei is explained using FIG. 33. One of features of the first embodiment is that there is an apparatus monitoring step of monitoring the sample observation apparatus on the basis of image quality evaluation values Ei. The sample observation apparatus regarded as a monitoring target here is the sample observation apparatus 1 (i.e., the subject apparatus) of the first embodiment in FIG. 1.

There has been a problem that, in a case where a captured image is used to judge whether there is an anomaly or the like in a sample observation apparatus, a human needs to visually check/judge the image, and this requires work cost and the like. In this regard, in the first embodiment, by using image quality evaluation values Ei, whether or not there is an anomaly or the like in the sample observation apparatus 1 is quantitatively judged. Consequently, the necessity for visual checking by a human is eliminated, and work cost and the like can be reduced.

FIG. 33 depicts Step S3300 of monitoring of a sample observation apparatus by use of image quality evaluation values Ei. First, at Step S3301, the computer system 3 receives an input of an image 201 that the sample observation apparatus 1 in FIG. 1 has captured with the SEM 2, and calculates an image quality evaluation value Ei 3302 of the image 201 at Step S3301 corresponding to Steps S2 and S3 in FIG. 2 mentioned before. Thereafter, at Step S3302, the computer system 3 judges whether or not there is an anomaly or the like in the sample observation apparatus 1, in other words, judges the apparatus state, using, as inputs, the image quality evaluation value Ei 3302 and normal range information 3303 concerning image quality evaluation values Ei. For example, the computer system 3 may determine that the apparatus state is normal (i.e., there are no anomalies) in a case where the image quality evaluation values Ei are in normal ranges in the normal range information 3303, and determine that the apparatus state is anomalous (i.e., there is an anomaly) in a case where the image quality evaluation values Ei are outside the normal ranges.

The normal range information 3303 concerning image quality evaluation values Ei is information specifying value ranges within which the respective image quality evaluation values Ei are regarded as being normal. The normal range information 3303 may be manually set by the user in user setting (Step S7). Alternatively, the normal range information 3303 may be automatically set by the computer system 3. In this case, for example, the computer system 3 may set the normal range information 3303 by use of a statistical distribution of image quality evaluation values Ei of an image captured by the sample observation apparatus 1 in its normal state.

In a case where, as a result of Step S3302, it is judged that there is an anomaly in the apparatus (YES), the procedure proceeds to Step S3303, and, in a case where it is judged that there are no anomalies (NO), the procedure proceeds to Step S3304. At Step S3303, the computer system 3 performs anomaly cause analysis related to the anomaly described above, and, as a result of the anomaly cause analysis, outputs a cause of anomaly 3306 (i.e., an anomaly cause analysis result).

For example, in a case where it is judged that there is an anomaly as a result of checking the image quality evaluation value E1 “sharpness” (FIG. 3) of the image 201, at Step S3303, the computer system 3 determines that there is an anomaly (i.e., a cause of anomaly) in an electrical axis of the SEM 2 (FIG. 1) related to the sharpness of the image 201, and outputs information to that effect. The electrical axis means a trajectory of an electron beam emitted from the electron gun 110.

At Step S3305, on the basis of the cause of anomaly 3306, the computer system 3 displays the apparatus state (there is an anomaly) and the cause of anomaly 3306 on, for example, a GUI screen, and the user can check them. On the basis of the cause of anomaly 3306, the user can implement adjustment of the position of a component related to the cause of anomaly 3306 in the sample observation apparatus 1, maintenance/replacement of the component, or the like as a measure.

Meanwhile, at Step S3304, the computer system 3 outputs normal information 3307 representing that there are no anomalies in the apparatus state.

### Advantages of First Embodiment, Etc.

As explained above, according to the sample observation apparatus and method of the first embodiment, quantification of the quality of an observation image becomes possible. According to the first embodiment, evaluation partial areas Si suited for respective image quality evaluation values Ei corresponding to various image quality items can be used, and preferable image quality quantification can be realized. According to the first embodiment, advantages attained by various functionalities (e.g., parameter adjustment of the image enhancement process mentioned before, etc.) can be realized using quantified image quality evaluation values Ei.

While an embodiment of the present disclosure has been explained specifically thus far, the present disclosure is not limited to the embodiment mentioned before and can be changed in various manners within the scope not departing from the gist. Addition, deletion, replacement, and the like of constituent elements of each embodiment are possible except for essential constituent elements. Unless otherwise particularly noted, the number of each constituent element may be one or may be greater than one. A form in which respective embodiments are combined is also possible.

### DESCRIPTION OF REFERENCE SYMBOLS

1: Sample observation apparatus
2: SEM (scanning electron microscope)
3: Computer system
10: Sample

1. A computer system in a sample observation apparatus for observing a sample, the computer system comprising:
at least one processor; and
at least one memory, wherein
the processor
determines a plurality of evaluation partial areas in an image captured of the sample, and
calculates a plurality of image quality evaluation values for evaluating a plurality of different image quality items by calculating an image quality evaluation value for each evaluation partial area on a basis of the plurality of evaluation partial areas.

2. The computer system according to claim 1, wherein
the plurality of image quality evaluation values include at least two of image sharpness, defect visibility, a degree of noise suppression, interlayer contrast, a degree of dark area emphasis, a degree of shape preservation, a degree of roughness preservation, a degree of ringing suppression, and image naturalness.

3. The computer system according to claim 1, wherein
the processor
performs classification for each of classification segmentation areas obtained by segmenting the image, and
determines the evaluation partial areas on a basis of a classification result of the classification segmentation areas.

4. The computer system according to claim 3, wherein
the processor performs the classification using sample information representing a structure of a semiconductor device which is the sample.

5. The computer system according to claim 3, wherein
the processor performs the classification using an image capturing condition of the image.

6. The computer system according to claim 3, wherein
the processor generates the evaluation partial areas by joining, segmenting, dilating, or eroding the classification segmentation areas or by a combination thereof.

7. The computer system according to claim 3, wherein
the classification of the classification segmentation areas includes classification into at least two of a wiring upper surface area, an edge area, a dark area, and a defective area in a semiconductor device which is the sample.

8. The computer system according to claim 1, wherein
the processor calculates a comprehensive evaluation value formed using a combination of the plurality of image quality evaluation values.

9. The computer system according to claim 1, wherein
the image quality evaluation values are calculated using an internal parameter on a basis of a setting, and
the processor determines a calculation method of the image quality evaluation values using the internal parameter, on a basis of an input of a result of evaluation by a user related to quality of the image, such that the image quality evaluation values match or approach the result of evaluation by the user.

10. The computer system according to claim 1, wherein
the image quality evaluation values are defined by a combination of a plurality of element image quality evaluation values on a basis of a setting.

11. The computer system according to claim 1, wherein
the processor determines a parameter value of an image quality enhancement process to be performed on the image, on a basis of the image quality evaluation values.

12. The computer system according to claim 11, wherein
the processor
sets an individual target value for at least one image quality evaluation value in the plurality of image quality evaluation values, and
adjusts the parameter value of the image quality enhancement process such that the image quality evaluation value approaches the target value.

13. The computer system according to claim 11, wherein
the processor
calculates a comprehensive evaluation value formed using a combination of the plurality of image quality evaluation values, and
adjusts the parameter value of the image quality enhancement process such that the comprehensive evaluation value is improved.

14. The computer system according to claim 1, wherein
the processor
causes the image, the evaluation partial areas, and the image quality evaluation values to be displayed on a screen, and
corrects the evaluation partial areas on a basis of an input by a user on the screen.

15. The computer system according to claim 1, wherein
the processor
performs benchmarking in which a first image and a second image which are used as the image are compared with each other in image quality, and,
in the benchmarking, compares the image quality evaluation values of the first image with the image quality evaluation values of the second image, and causes a comparison result to be displayed on a screen.

16. The computer system according to claim 1, wherein
the processor calculates the image quality evaluation values of the image captured of a semiconductor wafer which is the sample, selects an image for defect observation on a basis of the image quality evaluation values, and performs the defect observation of the selected image.

17. The computer system according to claim 1, wherein
the processor
calculates the image quality evaluation values of the image captured of a semiconductor wafer which is the sample,
adjusts an image capturing condition used in capturing of the image, on a basis of the image quality evaluation values, and
causes the image to be captured under the adjusted image capturing condition.

18. The computer system according to claim 1, wherein,
as monitoring of a state of the sample observation apparatus, the processor judges whether there is an anomaly in the sample observation apparatus, on a basis of the image quality evaluation values.

19. A sample observation method executed in a sample observation apparatus for observing a sample,
the computer system in the sample observation apparatus having at least one processor and at least one memory,
the sample observation method comprising, as steps executed by the processor:
a step of determining a plurality of evaluation partial areas in an image captured of the sample; and
a step of calculating a plurality of image quality evaluation values for evaluating a plurality of different image quality items by calculating an image quality evaluation value for each evaluation partial area on a basis of the plurality of evaluation partial areas.

20. A non-transitory computer-readable storage medium storing a program that is executed on a processor of a computer system to execute the sample observation method according to claim 19.
